(19) United States
(12) Patent Application Publication
(10) Pub. No.: US 2026/0047503 A1
(43) Pub. Date: Feb. 12, 2026

(54) SEMICONDUCTOR DEVICE AND METHOD FOR MANUFACTURING THE SAME

(71) Applicant: Mitsubishi Electric Corporation, Tokyo (JP)

(72) Inventors: Takuma NISHIMURA, Tokyo (JP); Hidenori YUKAWA, Tokyo (JP); Toru FUKASAWA, Tokyo (JP); Takumi NAGAMINE, Tokyo (JP); Yuji KOMATSUZAKI, Tokyo (JP)

(73) Assignee: Mitsubishi Electric Corporation, Tokyo (JP)

(21) Appl. No.: 19/363,226

(22) Filed: Oct. 20, 2025

Related U.S. Application Data
(63) Continuation of application No. PCT/JP2023/018188, filed on May 16, 2023.

(51) Int. Cl. H01L 25/065; H01L 23/66; H01L 25/00; H01P 3/08; H03F 3/04; H10D 80/20

(52) U.S. Cl. CPC H01L 25/0657; H01L 23/66; H01L 25/50; H01P 3/081; H10D 80/215; H10D 80/251; H01L 2223/6627; H01L 2225/0651; H01L 2225/06517; H01L 2225/06572; H01L 2225/06589; H03F 3/04

(57) ABSTRACT

A semiconductor device includes: a first substrate including first front side pads arranged around a front surface; a second substrate including second front side pads arranged around a front surface; a third substrate; first connection members each electrically connecting a corresponding first front side pad on the first substrate and a corresponding third back side pad on the third substrate; second connection members each electrically connecting a corresponding second front side pad on the second substrate and a corresponding third front side pad on the third substrate; a first resin layer that is in contact with a periphery of the front surface of the first substrate and a periphery of the back surface of the third substrate; and a second resin layer that is in contact with a periphery of the front surface of the second substrate and a periphery of the back surface of the third substrate.

### CROSS REFERENCE TO RELATED APPLICATIONS

This application is a Continuation of PCT International Application No. PCT/JP2023/018188 filed on May 16, 2023, all of which is hereby expressly incorporated by reference into the present application.

### TECHNICAL FIELD

The present disclosure relates to a semiconductor device on which a semiconductor element is mounted and a method for manufacturing the same.

### BACKGROUND ART

In the field of high frequency devices for communication and the like, an amplifier having high efficiency and a wide band is required, and Non Patent Literature 1 proposes a small semiconductor device having good heat dissipation and feasibility, on which a semiconductor element that is an amplifier for switching between a Doherty mode and an out-fading mode for each frequency is mounted.

The semiconductor device disclosed in Non Patent Literature 1 is a stacked package including a lower thick copper substrate including a two-input amplifier, an output combining circuit, an input circuit, and the like mounted in a dug portion, an upper thick copper substrate including a power supply, a driver amplifier, an input/output circuit, and the like mounted in the dug portion, and a multilayer interposer substrate disposed between the lower thick copper substrate and the upper thick copper substrate, which are each connected by solder balls containing copper core balls.

### CITATION LIST

### Non Patent Literature

Non Patent Literature 1: Nishimura et al., “Result of Study on Stacked Amplifier Package Using Thick Copper Substrate” 2022 Society Convention, the Institute of Electronics, Information and Communication Engineers, September 2022

### SUMMARY OF INVENTION

### Technical Problem

The semiconductor device disclosed in Non Patent Literature 1 has an advantage that good characteristics can be obtained while being miniaturized.

On the other hand, in this type of semiconductor device, improvement in environmental resistance and impact resistance is also desired.

The present disclosure has been made in view of the above points, and an object of the present disclosure is to obtain a semiconductor device that exhibits favorable characteristics even for wider bandwidth, is compact, and has improved environmental resistance and impact resistance.

### Solution to Problem

A semiconductor device according to the present disclosure includes: a first substrate on which a first semiconductor element is mounted, the first substrate including a plurality of first front side pads arranged around a front surface on a side on which the first semiconductor element is mounted; a second substrate on which a second semiconductor element is mounted, the second substrate including a plurality of second front side pads arranged around a front surface on a side on which the second semiconductor element is mounted, the second substrate being arranged in such a manner that the front surfaces face each other with respect to the first substrate; a third substrate disposed between the first substrate and the second substrate in such a manner as to face the front surface of the first substrate and the front surface of the second substrate, the third substrate having a plurality of third back side pads arranged around a back surface in such a manner as to face each of a plurality of first front side pads in the first substrate, and a plurality of third front side pads arranged around a front surface in such a manner as to face each of the plurality of second front side pads in the second substrate; a plurality of first connection members each electrically connecting a corresponding first front side pad of a plurality of first front side pads on the first substrate and a corresponding third back side pad of a plurality of third back side pads on the third substrate; a plurality of second connection members each electrically connecting a corresponding second front side pad of the plurality of second front side pads on the second substrate and a corresponding third front side pad of the plurality of third front side pads on the third substrate; a first resin layer that is in contact with a periphery of the front surface of the first substrate and a periphery of the back surface of the third substrate and has a hollow portion; and a second resin layer that is in contact with a periphery of the front surface of the second substrate and a periphery of the back surface of the third substrate and has a hollow portion wherein the first substrate includes a first dielectric substrate in which the plurality of first front side pads is formed around a front surface, a first wiring pattern layer formed on the front surface of the first dielectric substrate, and a first ground conductor constituted by thick copper formed on a back surface of the first dielectric substrate, and the first semiconductor element electrically connected to a line constituting the first wiring pattern layer is mounted and fixed on a front surface of the first ground conductor in a first opening reaching the front surface of the first ground conductor from the front surface of the first dielectric substrate, and the second substrate includes a second dielectric substrate in which the plurality of second front side pads is formed around a front surface, a second wiring pattern layer formed on the front surface of the second dielectric substrate, and a second ground conductor constituted by thick copper formed on a back surface of the second dielectric substrate, and the second semiconductor element electrically connected to a line constituting the second wiring pattern layer is mounted and fixed on a front surface of the second ground conductor in a second opening reaching the front surface of the second ground conductor from the front surface of the second dielectric substrate.

### Advantageous Effects of Invention

According to the present disclosure, since a first resin layer having a hollow portion in a periphery where a first dielectric substrate and an interposer substrate face each other and a second resin layer having a hollow portion in a periphery where a second dielectric substrate and the interposer substrate face each other are provided, environmental resistance and impact resistance are improved.

### BRIEF DESCRIPTION OF DRAWINGS

FIG. 1 is a cross-sectional view illustrating a semiconductor device according to a first embodiment.

FIG. 2 is a schematic diagram of the semiconductor device according to the first embodiment as viewed from a front surface of a first substrate.

FIG. 3 is a schematic diagram illustrating a connection relationship between a first semiconductor element and a wiring layer on the front surface of the first substrate of the semiconductor device in the first embodiment.

FIG. 4 is a diagram illustrating a resist on a front surface layer of the first substrate of the semiconductor device according to the first embodiment.

FIG. 5 is a rear view of the semiconductor device according to the first embodiment projected from the front surface of the first substrate.

FIG. 6 is a schematic diagram of the semiconductor device according to the first embodiment as viewed from a front surface of a second substrate.

FIG. 7 is a schematic diagram illustrating a connection relationship between a second semiconductor element and a third semiconductor element and a wiring layer on the front surface of the second substrate of the semiconductor device in the first embodiment.

FIG. 8 is a diagram illustrating a resist on a front surface layer of the second substrate of the semiconductor device according to the first embodiment.

FIG. 9 is a rear view of the semiconductor device according to the first embodiment projected from the front surface of the second substrate.

FIG. 10 is a diagram illustrating a conductor pattern on a front surface of a first layer in a third substrate of the semiconductor device according to the first embodiment.

FIG. 11 is a diagram illustrating a resist on the front surface of the first layer in the third substrate of the semiconductor device according to the first embodiment.

FIG. 12 is a diagram illustrating a conductor pattern on a front surface of a second layer in the third substrate of the semiconductor device according to the first embodiment.

FIG. 13 is a diagram illustrating a conductor pattern on a front surface of a third layer in the third substrate of the semiconductor device according to the first embodiment.

FIG. 14 is a diagram illustrating a conductor pattern on a front surface of a fourth layer in the third substrate of the semiconductor device according to the first embodiment.

FIG. 15 is a diagram illustrating a conductor pattern on a front surface of a fifth layer in the third substrate of the semiconductor device according to the first embodiment.

FIG. 16 is a diagram illustrating a conductor pattern on a back surface of a sixth layer in the third substrate of the semiconductor device according to the first embodiment.

FIG. 17 is a diagram illustrating a resist on the back surface of the sixth layer in the third substrate of the semiconductor device according to the first embodiment.

FIG. 18 is a cross-sectional view illustrating a semiconductor device according to a second embodiment.

FIG. 19 is a cross-sectional view illustrating a semiconductor device according to a third embodiment.

FIG. 20 is a cross-sectional view illustrating a semiconductor device according to a fourth embodiment.

FIG. 21 is a schematic diagram of the semiconductor device according to the fourth embodiment as viewed from a front surface of a first substrate.

FIG. 22 is a schematic diagram illustrating a connection relationship between a first semiconductor element and a wiring layer on the front surface of the first substrate of the semiconductor device in the fourth embodiment.

FIG. 23 is a diagram illustrating a resist on a front surface layer of the first substrate of the semiconductor device according to the fourth embodiment.

FIG. 24 is a rear view of the semiconductor device according to the fourth embodiment projected from the front surface of the first substrate.

FIG. 25 is a schematic diagram of the semiconductor device according to the fourth embodiment as viewed from a front surface of a second substrate.

FIG. 26 is a schematic diagram illustrating a connection relationship between a second semiconductor element and a wiring layer on the front surface of the second substrate of the semiconductor device in the fourth embodiment.

FIG. 27 is a diagram illustrating a resist on a front surface layer of the second substrate of the semiconductor device according to the fourth embodiment.

FIG. 28 is a rear view of the semiconductor device according to the fourth embodiment projected from the front surface of the second substrate.

FIG. 29 is a diagram illustrating a conductor pattern of a front surface layer in a third substrate of the semiconductor device according to the fourth embodiment.

FIG. 30 is a diagram illustrating a resist on a front surface of the front surface layer in the third substrate of the semiconductor device according to the fourth embodiment.

FIG. 31 is a diagram illustrating a conductor pattern of a back surface layer projected from a front surface in the third substrate of the semiconductor device according to the fourth embodiment.

FIG. 32 is a diagram illustrating a resist on a back surface of the back surface layer in the third substrate of the semiconductor device according to the fourth embodiment.

### DESCRIPTION OF EMBODIMENTS

### First Embodiment

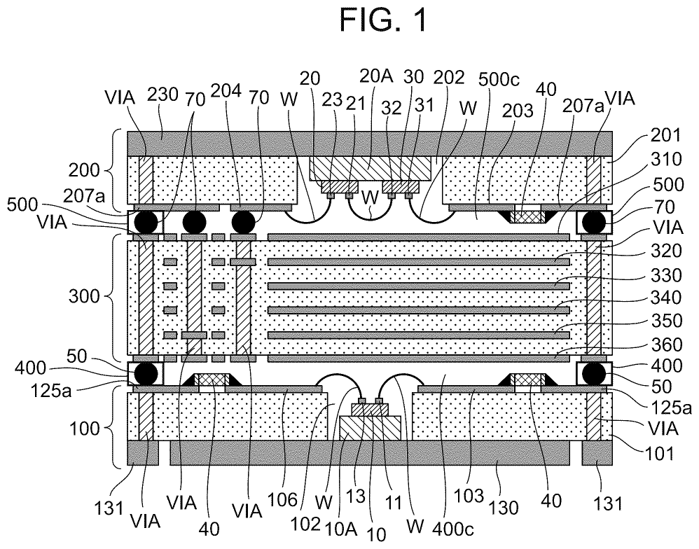

A semiconductor device according to a first embodiment will be described with reference to FIGS. 1 to 17.

The semiconductor device according to the first embodiment is a semiconductor device that is used in a high frequency device for communication or the like and is constituted by a stacked package on which a semiconductor element having a high output amplification function, a semiconductor element having a power supply control function, and a semiconductor element having a driver amplification function are mounted.

The semiconductor device according to the first embodiment is a wide-band GaN amplifier that switches between a Doherty mode and an out-fading mode for each frequency.

The semiconductor device according to the first embodiment is particularly a semiconductor device that is compact and has good environmental resistance and impact resistance while achieving ultra-wideband characteristics that can substantially cover the entire region of the Sub-6 band (band of 0.8 GHz or more and less than 5 GHz).

As illustrated in FIG. 1, the semiconductor device according to the first embodiment includes a first substrate 100 on which a first semiconductor element 10 is mounted, a second substrate 200 on which a second semiconductor element 20 and a third semiconductor element 30 are mounted, a third substrate 300 which is an interposer substrate, a first connection member 50, a second connection member 70, a first resin layer 400, and a second resin layer 500.

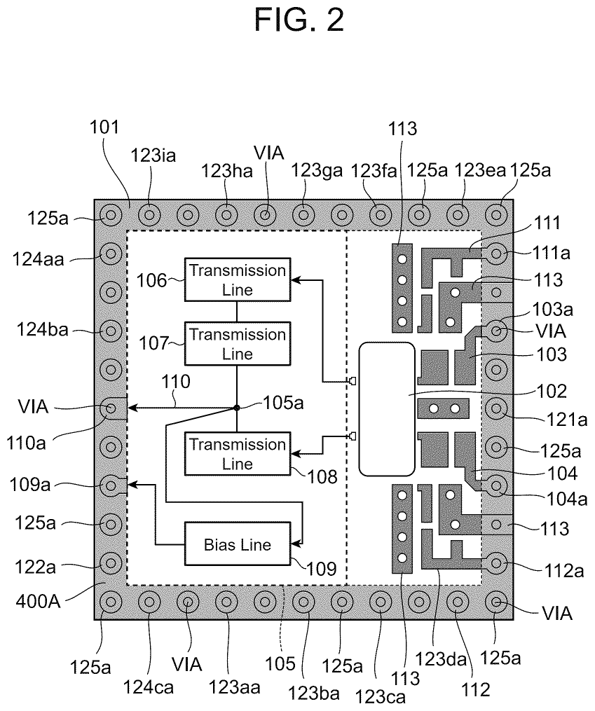

Note that the outer shapes of the first substrate 100, the second substrate 200, and the third substrate 300 as viewed from the front surface are represented by squares in FIG. 2 and subsequent drawings, but may be vertically long or horizontally long depending on the application, and are not limited to squares and may be rectangular.

The first semiconductor element 10 is a semiconductor element having a high output amplification function. The first semiconductor element 10 includes two amplifier circuits. The first semiconductor element 10 is a semiconductor element that easily generates heat. The characteristic impedance of the first semiconductor element 10 is, for example, 100Ω system.

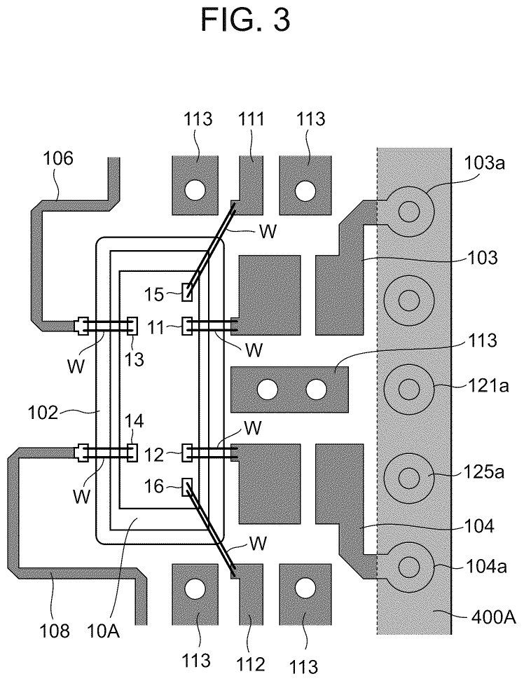

As illustrated in FIG. 3, the first semiconductor element 10 is a semiconductor element having two input terminals 11 and 12, two output terminals 13 and 14, and two bias terminals 15 and 16 on a front surface of a semiconductor substrate, in which a back surface of the semiconductor substrate is a ground layer.

Each terminal 11 to 16 is a pad formed on the front surface of the semiconductor substrate.

The first substrate 100 has a plurality of first front side pads on which the first semiconductor element 10 is mounted and which are arranged around the front surface on which the first semiconductor element 10 is mounted.

The first substrate 100 includes a first dielectric substrate 101 constituted by a single-layer insulating base material, a first wiring pattern layer formed on a front surface of the first dielectric substrate 101, the plurality of first front side pads formed around the front surface of the first dielectric substrate 101, a first ground conductor 130 of thick copper formed on a back surface of the first dielectric substrate 101, and a plurality of first back side pads.

In the first substrate 100, a first opening 102 reaching a front surface of the first ground conductor 130 from the front surface is formed in the first dielectric substrate 101, and in the first opening 102, the first semiconductor element 10 electrically connected to a line constituting the first wiring pattern layer is mounted and fixed on the front surface of the first ground conductor 130.

The first semiconductor element 10 is mounted on the first opening 102 with a first heat sink 10A interposed therebetween.

The ground layer on the back surface of the first semiconductor element 10 is grounded by the first ground conductor 130, and heat generated by the first semiconductor element 10 is dissipated via the first heat sink 10A and the first ground conductor 130.

Since the thickness of the first dielectric substrate 101 is a thickness up to the manufacturing limit for forming the first opening 102, a high-impedance line can be implemented as a line in the first wiring pattern layer formed on the front surface of the first dielectric substrate 101.

The first wiring pattern layer is formed of a conductor that is a copper foil having a thickness of, for example, 18 um or 35 um, and includes a transmission line that transmits a signal, a power supply line that supplies power (current) from a power supply, a bias line that supplies a bias potential, and a ground conductor that is a ground potential.

The first wiring pattern layer constitutes a part of a high frequency package or a high frequency module incorporating a high frequency circuit by the first semiconductor element 10 and a chip component 40 (only a part thereof is illustrated) such as a chip capacitor mounted by being electrically connected to a line constituting the first wiring pattern.

As illustrated in FIGS. 2 and 3, the first wiring pattern layer includes two input lines 103 and 104, a first transmission line 106 to a third transmission line 108 constituting an output combining circuit 105, a bias line 109, an output line 110, two bias lines 111 and 112, and a plurality of ground conductors 113.

As illustrated in FIG. 3, one input line 103 is connected to one input terminal 11 of the first semiconductor element 10 by wire bonding using a wire W such as a gold wire.

The number of wires W is illustrated in units of two in FIG. 3, but may be one or three or more.

The number of wires W for wire bonding described below may be two, one, or three or more.

One input line 103 is a generic term for a line extending from a position where one input terminal 11 of the first semiconductor element 10 is connected to one input pad 103a, and when a chip component (not illustrated) such as a chip capacitor is connected in the middle, one input circuit is configured. One input circuit in this case is a generally known input circuit.

Note that, in the present first embodiment, the description is given using a wire, but connection using another connection member such as a gold ribbon may be used as long as the connection member has a mountable pad size.

As illustrated in FIG. 3, the other input line 104 is connected to the other input terminal 12 of the first semiconductor element 10 by wire bonding using a wire W such as a gold wire.

The other input line 104 is a generic term for a line extending from a position where the other input terminal 12 of the first semiconductor element 10 is connected to another input pad 104a, and when a chip component (not illustrated) such as a chip capacitor is connected in the middle, the other input line constitutes the other input circuit. The other input circuit in this case is a generally known input circuit.

Each of the first transmission line 106 to the third transmission line 108 is a line having a high impedance of, for example, 100Ω as a characteristic impedance and an electrical length of 50 degrees to 90 degrees.

Note that, in the present disclosure, 100Ω does not strictly indicate only 100Ω, and includes a value in a range allowed in design for 100Ω.

Further, in the present disclosure, 50 degrees to 90 degrees do not strictly indicate only 50 degrees to 90 degrees, and include values in a range allowed by design for 50 degrees to 90 degrees.

As illustrated in FIG. 3, one end of the first transmission line 106 is connected to one output terminal 13 of the first semiconductor element 10 by wire bonding using a wire W such as a gold wire.

One end of the second transmission line 107 is connected to another end of the first transmission line 106, and the other end is connected to an output branch portion 105a of the output combining circuit 105.

The first transmission line 106 and the second transmission line 107 are lines that transmit the high-frequency amplified signal output from one output terminal 13 of the first semiconductor element 10 to the output branch portion 105a.

As illustrated in FIG. 3, one end of the third transmission line 108 is connected to the other output terminal 14 of the first semiconductor element 10 by wire bonding with wires W such as gold wires, and the other end is connected to the output branch portion 105a of the output combining circuit 105.

The third transmission line 108 is a line that transmits the high-frequency amplified signal output from the other output terminal 14 of the first semiconductor element 10 to the output branch portion 105a.

One end of the bias line 109 is connected to the output branch portion 105a of the output combining circuit 105, and the other end is connected to the bias pad 109a.

The bias line 109 is a generic term for lines extending from the output branch portion 105a of the output combining circuit 105 to the bias pad 109a, and a chip component (not illustrated) is connected in the middle to configure a bias circuit on the output side. The bias circuit is a generally known circuit.

The output line 110 is a line connected between the output branch portion 105a of the output combining circuit 105 and an output pad 110a.

When the output combining circuit 105 is configured using the first transmission line 106 to the third transmission line 108 having a high impedance near 100Ω as a characteristic impedance and the characteristic impedance of the first semiconductor element 10 is a 100Ω system, it is not necessary to use another matching circuit between the output pad 110a to which the 50Ω line system is connected, and between the first transmission line 106 and the third transmission line 108.

In addition, since the output combining circuit 105 is configured using the first transmission line 106 to the third transmission line 108 having an electrical length of about 50 degrees to 90 degrees, it is possible to efficiently switch the amplification mode of the first semiconductor element 10 using a difference in phase difference for each frequency.

Therefore, it is possible to implement ultra-wideband characteristics as an amplifier while maintaining miniaturization as a semiconductor device.

As illustrated in FIG. 3, one bias line 111 is connected to one bias terminal 15 of the first semiconductor element 10 by wire bonding using wires W.

One bias line 111 is a generic term for a line extending from a position where one bias terminal 15 of the first semiconductor element 10 is connected to one bias pad 111a, and when a chip component (not illustrated) such as a chip capacitor is connected in the middle, the one bias line 111 constitutes a bias circuit on one input side. One bias circuit in this case is a generally known bias circuit.

As illustrated in FIG. 3, the other bias line 112 is connected to the other bias terminal 16 of the first semiconductor element 10 by wire bonding using wires W.

The other bias line 112 is a generic term for a line extending from a position where the other bias terminal 16 of the first semiconductor element 10 is connected to the other bias pad 112a, and when a chip component (not illustrated) such as a chip capacitor is connected in the middle, a bias circuit on the other input side is formed. The other bias circuit in this case is a generally known bias circuit.

As illustrated in FIGS. 2 and 3, each of the plurality of ground conductors 113 is arranged between adjacent transmission lines to prevent interference between signals or the like between the adjacent transmission lines.

Each of the plurality of ground conductors 113 is electrically connected to the first ground conductor 130 formed on the back surface of the first dielectric substrate 101 by a via (VIA) indicated by a circle mark “∘” in FIG. 2 in the ground conductor 113.

Note that, among the plurality of ground conductors 113, the ground conductor 113 extending to the side of the first dielectric substrate 101 and having a line width larger than the diameter of the pad also serves as a ground pad 113a whose end is connected to the via VIA.

In the present first embodiment, the plurality of first front side pads formed on the front surface of the first dielectric substrate 101 is formed by a conductor that is a copper foil simultaneously with the wiring pattern layer along four sides of the first dielectric substrate 101, and 11 front side pads are provided on each side.

However, the number of front side pads is not limited to 11 since it can be changed according to the size of the first dielectric substrate 101, the manufacturing rule of the substrate, and the required specifications.

In addition to one input pad 103a, the other input pad 104a, the bias pad 109a, the output pad 110a, the bias pad 111a, the bias pad 112a, and the ground pad 113a, the plurality of first front side pads include an input pad 121a, an output pad 122a, bias pads 123aa to 123ia, and bias pads 124aa to 124ca, which are electrically connected to the corresponding pads of the second substrate 200 via the third substrate 300, and a ground pad 125a other than them.

Each front side pad is selected from the plurality of first front side pads depending on the line of the first wiring pattern layer.

Each of the plurality of front side pads is electrically connected to the plurality of first back side pads formed on the first back surface of the first dielectric substrate 101 facing each other via the via VIA.

Each of the plurality of first front side pads is electrically and physically connected to a corresponding one of a plurality of third back side pads of the third substrate 300 by the first connection member 50 such as a solder ball as partially illustrated in FIG. 1.

As the first connection member 50, a solder ball containing a copper core ball may be used as long as flatness can be secured. In addition, a conductive adhesive member according to specifications such as a normal solder ball not containing a copper core ball, a copper pillar, and a gold bump may be used.

Hereinafter, the first connection member 50 will be described as a solder ball 50.

The solder balls 50 are first conductive connection members that each electrically connect a corresponding first front side pad of the plurality of first front side pads on the first substrate 100 and a corresponding third back side pad of the plurality of third back side pads on the third substrate 300.

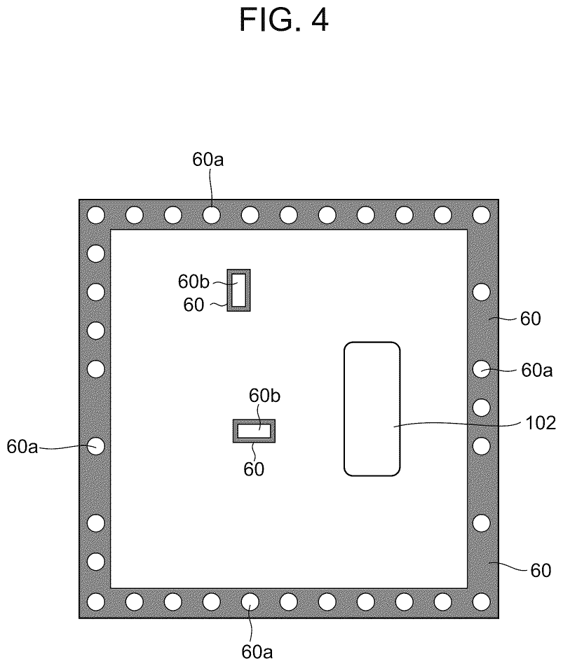

A resist film 60 is formed on the front surface of the first dielectric substrate 101, and as illustrated in FIG. 4, has a circular opening 60a for exposing front surfaces of the input pad 121a, the output pad 122a, the bias pads 123aa to 123ia, the bias pads 124aa to 124ca, and the ground pad 125a corresponding to the second substrate 200, and for mounting solder balls 50, and a rectangular opening 60b for mounting a chip component (not illustrated).

The resist film 60 covers front surfaces of the one input pad 103a, the other input pad 104a, the bias pad 109a, the output pad 110a, the bias pad 111a, and the bias pad 112a, prevents a solder flow when the solder ball 50 is mounted, and enables protection of the front side pad and uniform adhesion of the solder ball 50.

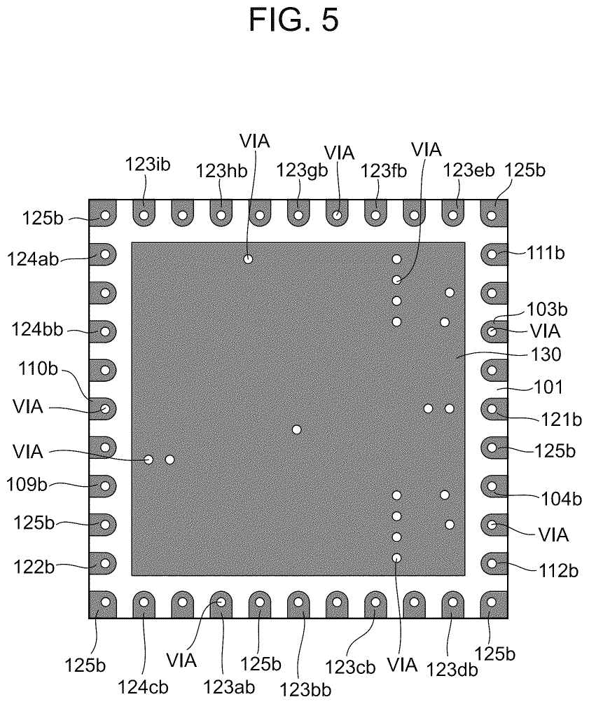

As illustrated in FIG. 5, the first ground conductor 130 formed on the back surface of the first dielectric substrate 101 is formed by patterning a conductor which is a thick copper foil having a thickness of 100 um or more, in the present first embodiment, 200 um in the central portion excluding the periphery.

The first ground conductor 130 is electrically connected to each of the plurality of ground conductors 113 formed on the front surface of the first dielectric substrate 101 by a via VIA indicated by a circle mark “∘” in the drawing in the first ground conductor 130.

In the first ground conductor 130, the first semiconductor element 10 is mounted and fixed on the exposed surface of the first dielectric substrate 101 located in the first opening 102 via the first heat sink 10A.

Since the first ground conductor 130 is a conductor which is a thick copper foil, heat diffusibility is good, and heat dissipation is excellent with respect to heat generated by the first semiconductor element 10 and rigidity is excellent, so that warpage of the first dielectric substrate 101 can be reduced.

The first ground conductor 130 is mounted and fixed on a ground layer formed on a front surface of a mounting substrate (not illustrated) by soldering or the like, and is grounded by the ground layer of the mounting substrate.

The plurality of first back side pads formed on the back surface of the first dielectric substrate 101 is formed by patterning a conductor that is a thick copper foil simultaneously with the first ground conductor 130 along the four sides of the first dielectric substrate 101.

Each of the plurality of first back side pads is arranged to face each of the plurality of first front side pads formed on the front surface, and is electrically connected to each of the plurality of first front side pads via a via VIA penetrating the first dielectric substrate 101.

In addition to the one input pad 103b, the other input pad 104b, the output-side bias pad 109b, the output pad 110b, the one input-side bias pad 111b, the other input-side bias pad 112b, and the ground pad 113b, the plurality of first back side pads includes an input pad 121b, an output pad 122b, bias pads 123ab to 123ib, and bias pads 124ab to 124cb corresponding to the second substrate 200, and the ground pad 125a other than them.

Each back side pad is electrically connected to a corresponding wiring layer formed on the front surface of the mounting substrate (not illustrated) by soldering or the like.

Since the wiring pattern layer is surrounded by the plurality of ground pads 125a on the front side, a plurality of ground pads 125b on the back side, and vias VIA connecting the ground pads 125a and 125b, a structure resistant to intrusion of noise from the outside is obtained.

Note that, in FIG. 1, the plurality of first back side pads is not denoted by individual reference numerals, but is denoted by reference numeral 131 as a general term for convenience of description.

The second semiconductor element 20 is a semiconductor element in which an amount of heat generated during operation is smaller than an amount of heat generated during operation of the first semiconductor element 10.

The second semiconductor element 20 is a semiconductor element having a power supply control function.

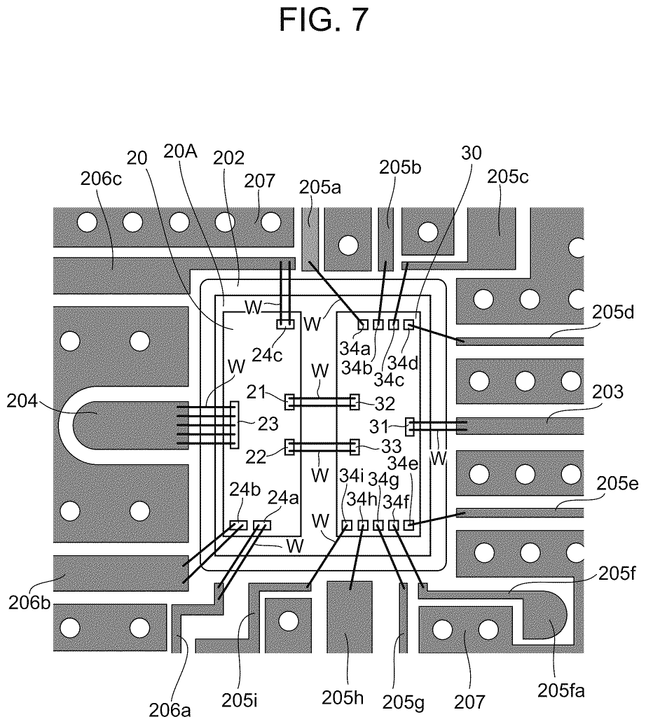

As illustrated in FIG. 7, the second semiconductor element 20 is a semiconductor element having two input terminals 21 and 22, an output terminal 23, and three bias terminals 24a to 24c on the front surface of the semiconductor substrate.

Each of the terminals 21 to 23 and 24a to 24c is a pad formed on the front surface of the semiconductor substrate.

The third semiconductor element 30 is a semiconductor element in which an amount of heat generated during operation is smaller than an amount of heat generated during operation of the first semiconductor element 10.

The third semiconductor element 30 is a semiconductor element having a driver amplification function.

As illustrated in FIG. 7, the third semiconductor element 30 is a semiconductor element having an input terminal 31, two output terminals 32 and 33, and nine bias terminals 34a to 34i on the front surface of the semiconductor substrate.

Each of the terminals 31 to 33 and 34a to 34i is a pad formed on the front surface of the semiconductor substrate.

The two output terminals 32 and 33 of the third semiconductor element 30 are respectively connected to the corresponding two input terminals 21 and 22 of the second semiconductor element 20 by wire bonding using wires W such as gold wires.

As illustrated in FIG. 1, on the second substrate 200, the second semiconductor element 20 and the third semiconductor element 30 are mounted, a plurality of second front side pads arranged around a front surface on which the second semiconductor element 20 and the third semiconductor element 30 are mounted is provided, the second substrate 200 being arranged in such a manner that the front surfaces face each other with respect to the first substrate 100.

The second substrate 200 includes a second dielectric substrate 201 constituted by a single-layer insulating base material, a second wiring pattern layer formed on the front surface of the second dielectric substrate 201, a plurality of second front side pads formed around the front surface of the second dielectric substrate 201, and a second ground conductor 230 constituted by thick copper formed on the back surface of the second dielectric substrate 201.

In the second substrate 200, a second opening 202 reaching the front surface of the second ground conductor 230 from the front surface is formed in the second dielectric substrate 201, and in the second opening 202, the second semiconductor element 20 and the third semiconductor element 30 electrically connected to the lines constituting the second wiring pattern layer are mounted and fixed on the front surface of the second ground conductor 230.

The second semiconductor element 20 is mounted on the second opening 202 with a second heat sink 20A interposed therebetween.

The back surface of the second semiconductor element 20 is mounted and fixed on the second ground conductor 230 with the second heat sink 20A interposed therebetween, and the heat generated by the second semiconductor element 20 is dissipated via the second heat sink 20A and the second ground conductor 230. Similarly to the second semiconductor element 20, the third semiconductor element 30 is mounted on the second opening 202 with a second heat sink 20A interposed therebetween.

The back surface of the third semiconductor element 30 is mounted and fixed on the second ground conductor 230 with the second heat sink 20A interposed therebetween, and the heat generated by the third semiconductor element 30 is dissipated via the second heat sink 20A and the second ground conductor 230.

In the present first embodiment, the second dielectric substrate 201 is the same insulating base material as the first dielectric substrate 101.

The thickness of the second dielectric substrate 201 is the same as the thickness of the first dielectric substrate 101, and is a thickness up to a manufacturing limit for forming the second opening 202.

In this manner, even in the semiconductor device in which the first substrate 100 and the second substrate 200 are stacked without the third substrate 300 described in the first embodiment, the thermal stress applied to the first substrate 100 and the second substrate 200 is substantially the same when the semiconductor device is mounted using the solder balls 50, so that highly accurate mounting and failure prevention are achieved.

In a semiconductor device of a type in which the second substrate 200 is directly stacked on the first substrate 100, each of the solder balls 50 serves as a connection member that electrically connects the corresponding first front side pad among the plurality of first front side pads on the first substrate 100 and the corresponding second front side pad among the plurality of second front side pads on the second substrate 200.

The second wiring pattern layer is constituted by the same material and has the same thickness as the first wiring pattern layer.

The second wiring pattern layer is formed of a conductor that is a copper foil having a thickness of, for example, 18 um or 35 um, and includes a transmission line that transmits a signal, a power supply line that supplies power (current) from a power supply, a bias line that supplies a bias potential, and a ground conductor that is a ground potential.

The second wiring pattern layer constitutes a part of a high frequency package or a high frequency module incorporating a high frequency circuit by the second semiconductor element 20, the third semiconductor element 30, and the chip component 40 (only a part thereof is illustrated) such as a chip capacitor mounted by being electrically connected to a line constituting the second wiring pattern.

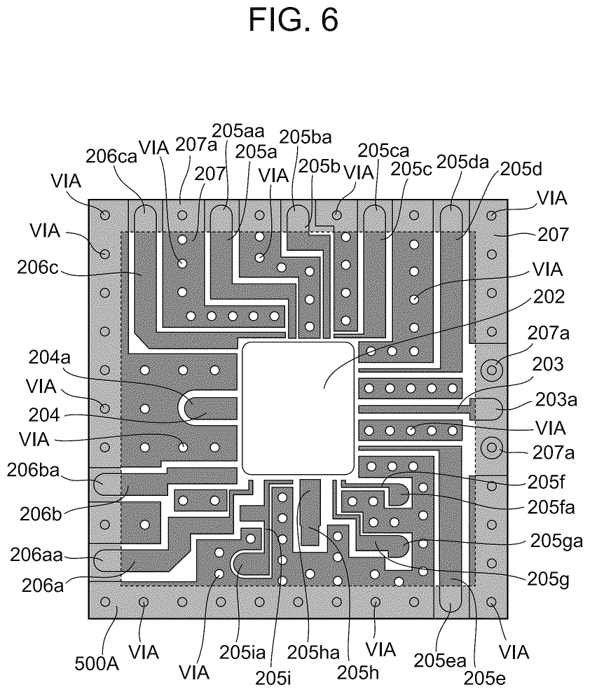

As illustrated in FIGS. 6 and 7, the second wiring pattern layer includes an input line 203, an output line 204, nine bias lines 205a to 205i on the input side, three bias lines 206a to 206c on the output side, and a plurality of ground conductors 207.

The input line 203 is connected to the input terminal 31 of the third semiconductor element 30 by wire bonding using a wire W such as a gold wire.

The number of wires W is illustrated in units of two in FIG. 7, but may be one or three or more since it only needs to be selected from the viewpoint of input/output power, withstand power, and the like.

Although the description will be given using a wire, connection using another connection member such as a gold ribbon may be used as long as the connection member has a mountable pad size.

The input line 203 is a generic term for a line extending from a position where input terminal 31 of the third semiconductor element 30 is connected to an input pad 203a.

The output line 204 is connected to the output terminal 23 of the second semiconductor element 20 by wire bonding using a wire W such as a gold wire.

The output line 204 is a generic term for a line extending from a position where the output terminal 23 of the second semiconductor element 20 is connected to the output pad 204a.

The bias lines 205a to 205i on the input side are connected to the bias terminals 34a to 34i of the corresponding third semiconductor element 30 by wire bonding with the wires W.

Each of the bias lines 205a to 205i is a generic term for a line extending from a position where the bias terminals 34a to 34i of the third semiconductor element 30 are connected to the corresponding bias pads 205aa to 205ia.

Note that, as an example, the number of the bias lines 205a to 205i on the input side is nine in accordance with the bias terminals 34a to 34i of the third semiconductor element 30, but the number decreases as the bias terminals of the third semiconductor element 30 decrease, and the number increases as the bias terminals increase.

The bias lines 206a to 206c on the output side are connected to the corresponding bias terminals 24a to 24c of the second semiconductor element 20 by wire bonding with the wires W.

Each of the bias lines 206a to 206c is a generic term for a line extending from a position where the bias terminals 24a to 24c of the second semiconductor element 20 are connected to the corresponding bias pads 206aa to 206ca.

Note that, as an example, three bias lines 206a to 206c on the output side are provided in accordance with the bias terminals 24a to 24c of the second semiconductor element 20, but the number decreases as the bias terminals of the second semiconductor element 20 decrease, and the number increases as the bias terminals increase.

Each of the input line 203, the output line 204, the bias lines 205a to 205i on the input side, and the bias lines 206a to 206c on the output side is formed to such an extent that they are not coupled to each other, and has a pattern satisfying a required size, for example, a bent shape.

As illustrated in FIGS. 6 and 7, each of the plurality of ground conductors 207 is arranged between adjacent transmission lines to prevent interference between signals or the like between the adjacent transmission lines.

Each of the plurality of ground conductors 207 is electrically connected to the second ground conductor 230 formed on the back surface of the second dielectric substrate 201 by a via VIA indicated by circle marks “∘” in FIG. 6 in the ground conductor 207.

Note that, among the plurality of ground conductors 207, in the ground conductor 207 extending to the side of the second dielectric substrate 201 and having a line width larger than the diameter of the pad, the position of the ground conductor 207 connected to the via VIA located on the side of the second dielectric substrate 201 also serves as the ground pad 207A.

In the present first embodiment, the plurality of front side pads formed on the front surface of the second dielectric substrate 201 includes 11 pads on each side formed by patterning a conductor that is a copper foil simultaneously with the wiring pattern layer along four sides of the second dielectric substrate 201, the output pad 204a, and bias pads 205fa to 205ia. However, the number of pads on each side is not limited to 11.

The plurality of second front side pads arranged on the four sides of the second dielectric substrate 201 includes the input pad 203a, bias pads 205aa to 205ea on the input side, bias pads 206aa to 206ac on the output side, and a ground pad 207a other than these.

Each second front side pad is selected from the plurality of front side pads depending on the line of the second wiring pattern layer.

Each of the ground pads 207a is electrically connected to the second ground conductor 230 formed on the back surface of the second dielectric substrate 201 via the via VIA penetrating the second dielectric substrate 201.

Each of the plurality of second front side pads is electrically and physically connected to each of the corresponding plurality of third front side pads of the third substrate 300 by a second connection member 70 such as a solder ball as partially illustrated in FIG. 1.

As the second connection member 70, a solder ball containing a copper core ball may be used as long as flatness can be secured. In addition, a conductive adhesive member according to specifications such as a normal solder ball not containing a copper core ball, a copper pillar, and a gold bump may be used.

Hereinafter, the second connection member 70 will be described as a solder ball 70.

The solder balls 70 are a plurality of second conductive connection members each electrically connecting a corresponding second front side pad of the plurality of second front side pads on the second substrate 200 and a corresponding third front side pad of the plurality of third front side pads on the third substrate 300.

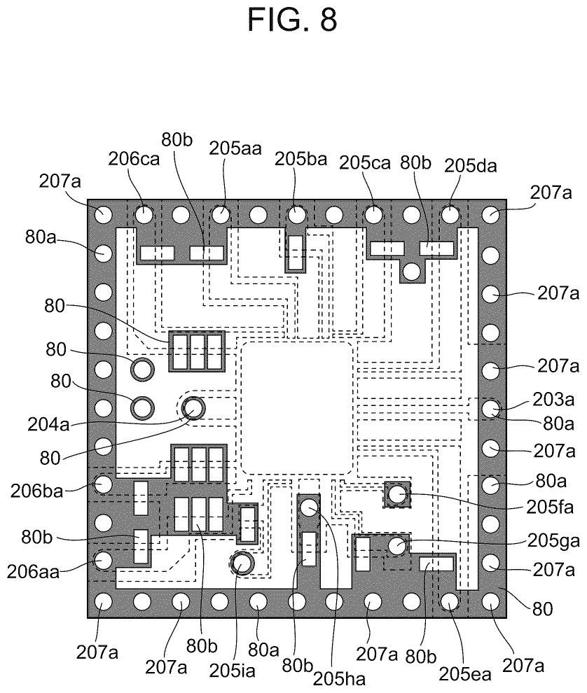

The resist film 80 is formed on the front surface of the second dielectric substrate 201, exposes the front surfaces of all of the plurality of front side pads formed on the front surface of the second dielectric substrate 201, and has a circular opening 80a for mounting solder balls 70 and a rectangular opening 80b for mounting a chip component (not illustrated), as illustrated in FIG. 8.

The second ground conductor 230 formed on the back surface of the second dielectric substrate 201 is constituted by the same material and has the same thickness as the first ground conductor 130 formed on the back surface of the first dielectric substrate 101.

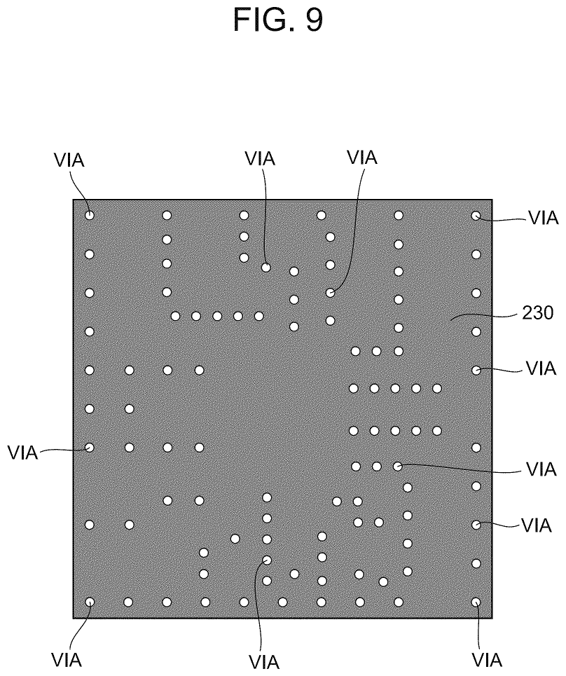

As illustrated in FIG. 9, the second ground conductor 230 is formed on the entire back surface of the second dielectric substrate 201 by a conductor that is a thick copper foil having a thickness of 100 um or more, 200 um in the present first embodiment.

The second ground conductor 230 is electrically connected to each of the plurality of ground conductors 207 and the ground pads 207A formed on the front surface of the second dielectric substrate 201 by a via VIA indicated by circle marks “∘” in the drawing in the second ground conductor 230.

Similarly to the first substrate 100, in the second ground conductor 230, the second semiconductor element 20 and the third semiconductor element 30 are mounted and fixed on the exposed surface of the second dielectric substrate 201 located in the second opening 202 via the second heat sink 20A.

Since the second ground conductor 230 is a conductor which is a thick copper foil, heat diffusibility is good, and heat dissipation is excellent with respect to heat generated by the second semiconductor element 20 and the third semiconductor element 30.

In addition, since the second ground conductor 230 is formed of a copper foil thicker than a normal resin substrate and has excellent rigidity, warpage of the second dielectric substrate 201 can be reduced.

The first semiconductor element 10, the first wiring pattern layer formed on the front surface of the first dielectric substrate 101, the chip component 40 (only a part thereof is illustrated) such as a chip capacitor electrically connected to a line constituting the first wiring pattern, the second semiconductor element 20, the third semiconductor element 30, the second wiring pattern layer formed on the front surface of the second dielectric substrate 201, and the chip component 40 (only a part thereof is illustrated) such as a chip capacitor electrically connected to a line constituting the second wiring pattern constitute a part of a high frequency package or a high frequency module incorporating a high frequency circuit.

The first substrate 100 and the second substrate 200 have the same thickness as a whole, and the thicknesses and materials of constituent elements thereof are also the same.

That is, the first dielectric substrate 101 and the second dielectric substrate 201 are constituted by the same material and have the same thickness, the first wiring pattern layer and the second wiring pattern layer are constituted by the same material and have the same thickness, and the first ground conductor 130 and the second ground conductor 230 are constituted by the same material and have the same thickness.

Further, as illustrated in FIG. 1, when the first substrate 100 and the second substrate 200 are stacked, the front surface of the first substrate 100 and the front surface of the second substrate 200 are disposed to face each other, that is, the first wiring pattern layer and the second wiring pattern layer are disposed to face each other.

As illustrated in FIG. 1, the third substrate 300 is disposed between the first substrate 100 and the second substrate 200 in such a manner as to face the front surface of the first substrate 100 and the front surface of the second substrate 200, has a plurality of third back side pads arranged around the back surface in such a manner as to face a plurality of first front side pads formed around the front surface of the first dielectric substrate 101 in the first substrate 100, and each connected to the corresponding first front side pad by the solder balls 50, and has a plurality of third front side pads arranged around the front surface in such a manner as to face a plurality of second front side pads formed around the front surface of the second dielectric substrate 201 in the second substrate 200, and each connected to the corresponding second front side pad by the solder balls 70.

In the present first embodiment, the third substrate 300 is an interposer substrate having a multilayer structure that relays electrical connection between the first substrate 100 and the second substrate 200.

The third substrate 300 is an interposer substrate having a six-layer structure in the present first embodiment.

The front surface side of the third substrate 300, that is, the uppermost layer will be described as the first layer, and the back surface side, that is, the lowermost layer will be described as the sixth layer. The second to fifth layers are intermediate layers, and in particular, there are an intermediate layer in which a line is formed and an intermediate layer to be a ground layer.

In order to eliminate the complexity of the description, the pattern of the front surface in the first layer of the third substrate 300, that is, the pattern of the first layer (uppermost layer) is simply abbreviated as a first-layer pattern. The second to sixth layers (lowermost layers) will also be briefly described.

The first-layer pattern to the sixth-layer pattern are formed by a conductor which is a copper foil having a thickness of, for example, 18 um or 35 um.

Further, an insulating layer is interposed between adjacent patterns.

The third substrate 300 is a relay substrate that has pads arranged in a central portion on the front surface of the second substrate 200, in the present first embodiment, pads arranged to face the output pad 204a and the bias pads 205fa to 205ia in the first-layer pattern, and pads arranged to face the input pad 121a, the output pad 122a, the bias pads 123aa to 123ia, the bias pads 124aa to 124ca, and the ground pads 125a, arranged along sides on the front surface of the first substrate 100, in the sixth-layer pattern, and connects corresponding pads in the pads in the first-layer pattern and the pads in the sixth-layer pattern.

Further, in the third substrate 300, the first-layer pattern is a first pad layer that connects the output pad 204a and the bias pads 205fa to 205ia on the front surface of the second substrate 200, the second-layer pattern and the fifth-layer pattern are a first wiring layer and a second wiring layer, the third-layer pattern and the fourth-layer pattern are a first ground layer and a second ground layer, and the sixth-layer pattern is a second pad layer that connects the input pad 121a, the output pad 122a, the bias pads 123aa to 123ia, and the bias pads 124aa to 124ca on the front surface of the first substrate 100.

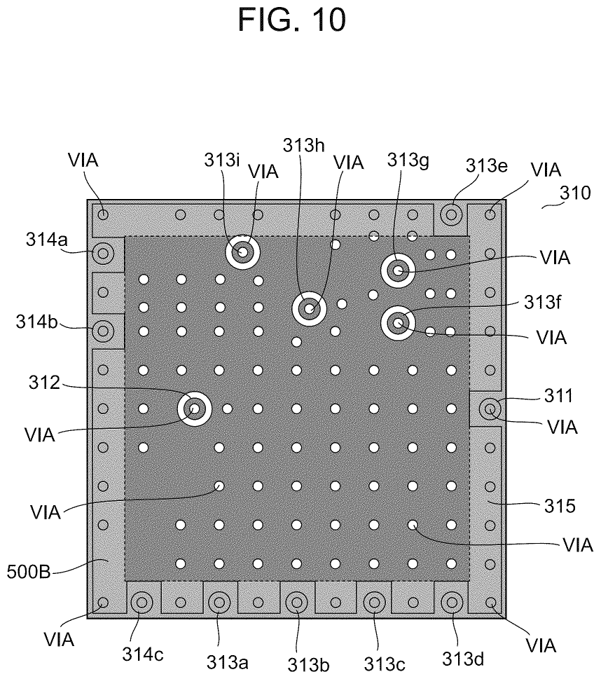

A pattern of each layer in the third substrate 300 will be described with reference to FIGS. 10 to 17.

As illustrated in FIG. 10, a first-layer pattern 310 is a pattern on the front surface of the third substrate 300, and is a pad layer connected to the second front side pads of the second substrate 200 by the solder balls 70.

The first-layer pattern 310 includes an input pad 311, an output pad 312, bias pads 313a to 313i, and bias pads 314a to 314c at positions facing the input pad 203a, the output pad 204a, the bias pads 205aa to 205ia, and the bias pads 206aa to 206ca, respectively, formed on the front surface of the second substrate 200.

Further, the first-layer pattern 310 includes a ground layer 315 which is a solid pattern electrically insulated from the input pad 311, the output pad 312, the bias pads 313a to 313i, and the bias pads 314a to 314c in a region excluding these pads.

In FIG. 10, the ground layer 315 is electrically connected to the ground layer located in the lower layer by a via VIA indicated by circle marks “∘” in FIG. 10 in the ground layer 315.

Note that, in the ground layer 315, a portion connected to the vias VIA located along the four sides also serves as a ground pad 315a.

The input pad 311 is connected by a via VIA penetrating from the first-layer pattern to the sixth-layer pattern.

The output pad 312 is connected by a vias VIA penetrating from the first-layer pattern to the second-layer pattern.

Similarly to the input pad 311, the bias pads 313a to 313e are connected by vias VIA penetrating from the first-layer pattern to the sixth-layer pattern.

Similarly to the output pad 312, the bias pads 313g and 313i are connected by vias VIA penetrating from the first-layer pattern to the second-layer pattern.

The bias pads 313f and 313h are connected by vias VIA penetrating from the first-layer pattern to the fifth-layer pattern.

The bias pads 314a to 314c are connected by vias VIA penetrating from the fifth-layer pattern to the sixth-layer pattern.

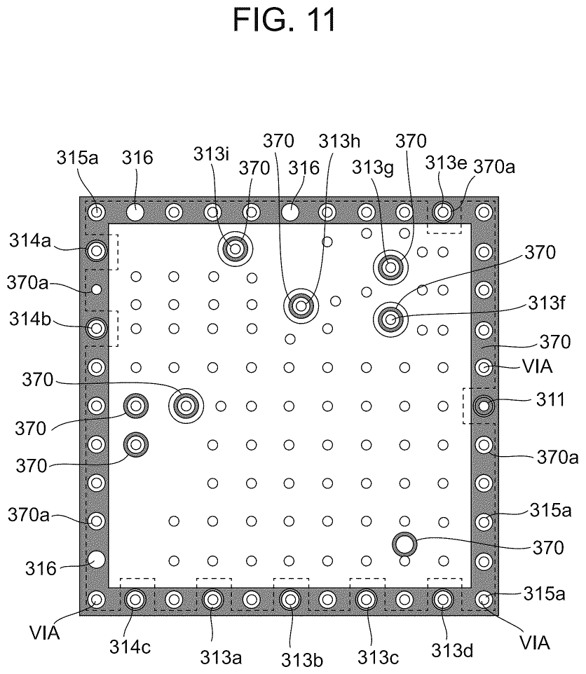

A resist film 370 is formed on a front surface of the first-layer pattern 310, and as illustrated in FIG. 11, has a circular opening 370a for exposing front surfaces of the input pad 311, the output pad 312, the bias pads 313a to 313i, the bias pads 314a to 314c, and the ground pad 315a and mounting the solder balls 70.

Note that, in FIG. 11, no via VIA exists at positions of circle marks “,” indicated by reference numeral 316, and the ground layer 315 is not electrically connected to the second-layer pattern at the position indicated by reference numeral 316.

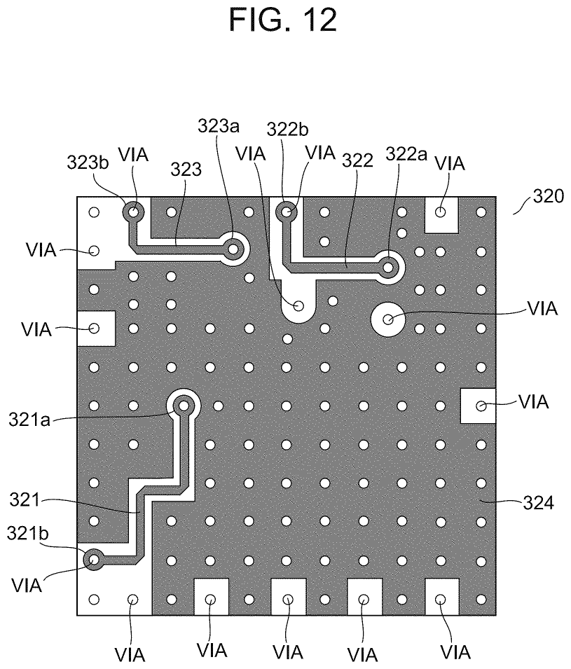

As illustrated in FIG. 12, a second-layer pattern 320 includes a first line 321, a second line 322, and a third line 323.

Further, the second-layer pattern 320 includes a ground layer 324 which is a solid pattern electrically insulated from the vias VIA except for the vias VIA connected to the input pad 311, the bias pads 313a to 313e, 313f, and 313h, and the bias pads 314a to 314c.

The ground layer 324 is electrically connected to the ground layers located in the upper layer and the lower layer by vias VIA indicated by circle marks “∘” in FIG. 12 in the ground layer 324.

In the first line 321, one end 321a is connected to the via VIA connected to the output pad 312 in the first-layer pattern 310, and the other end 321b is connected to the via VIA connected to an output pad 362 in the sixth-layer pattern.

In the second line 322, one end 322a is connected to the via VIA connected to the bias pad 313g in the first-layer pattern 310, and the other end 322b is connected to the via VIA connected to the bias pad 363g in the sixth-layer pattern.

In the third line 323, one end 323a is connected to the via VIA connected to the bias pad 313i in the first-layer pattern 310, and the other end 323b is connected to the via VIA connected to the bias pad 363i in the sixth-layer pattern.

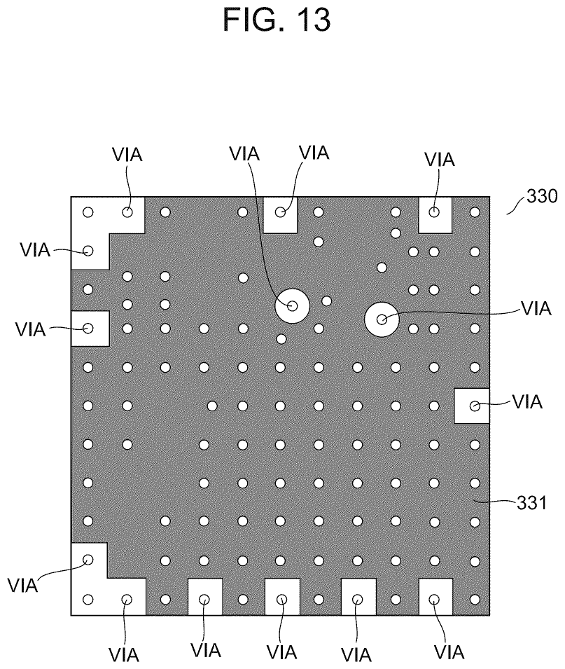

As illustrated in FIG. 13, a third-layer pattern 330 is a layer in which a region other than vias VIA excluding vias VIA set to the ground potential is set as a ground layer 331.

The ground layer 331 is electrically connected to the ground layers located in the upper layer and the lower layer by vias VIA indicated by circle marks “∘” in FIG. 13 in the ground layer 331.

The third-layer pattern 330 is a solid pattern electrically insulated from vias VIA that electrically connect the input pad 311, the bias pads 313a to 313e, and the bias pads 314a to 314c in the first-layer pattern 310 and the corresponding input pad 361, bias pads 363a to 363e, and bias pads 364a to 364c in a sixth-layer pattern 360, vias VIA that electrically connect the other end 321b of the first line 321, the other end 322b of the second line 322, and the other end 323b of the third line 323 in the second-layer pattern 320 and the corresponding output pad 362 and bias pads 313g and 313i in the sixth-layer pattern 360, and a via VIA that electrically connect the bias pads 313f and 313h in the first-layer pattern 310 and the corresponding one end of the corresponding fourth line and the corresponding one end of the fifth line in the fifth-layer pattern 350.

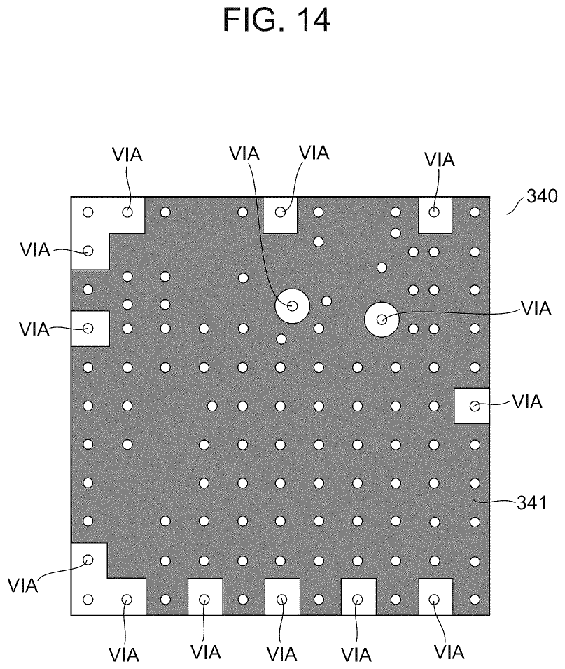

As illustrated in FIG. 14, a fourth-layer pattern 340 is a layer in which a region other than vias VIA excluding vias VIA set to the ground potential is set as the ground layer 341.

The ground layer 341 is electrically connected to the ground layers located in the upper layer and the lower layer by vias VIA indicated by circle marks “∘” in FIG. 14 in the ground layer 341.

The fourth-layer pattern 340 is a solid pattern having the same shape as the third-layer pattern 330.

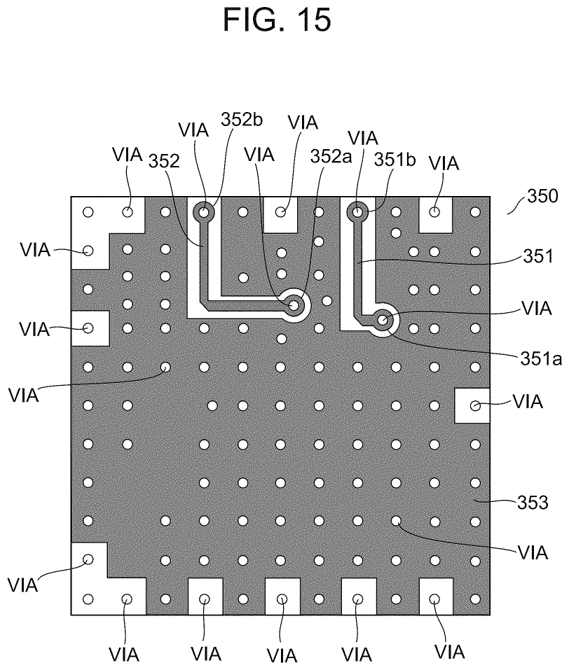

As illustrated in FIG. 15, the fifth-layer pattern 350 includes a fourth line 351 and a fifth line 352.

In addition, the fifth-layer pattern 350 includes a ground layer 353 that is a solid pattern electrically insulated from vias VIA except for the via VIA connected to the input pad 361, the output pad 362, the bias pads 363a to 363e, 363g, and 363i, and the bias pads 364a to 364c in the sixth-layer pattern 360.

The ground layer 353 is electrically connected to the ground layers located in the upper layer and the lower layer by vias VIA indicated by circle marks “∘” in FIG. 15 in the ground layer 353.

In the fourth line 351, one end 351a is connected to the via VIA connected to the bias pad 313f in the first-layer pattern 310, and the other end 351b is connected to the via VIA connected to the bias pad 363f in the sixth-layer pattern.

In the fifth line 352, one end 352a is connected to the via VIA connected to the bias pad 313h in the first-layer pattern 310, and the other end 352b is connected to the via VIA connected to the bias pad 363h in the sixth-layer pattern.

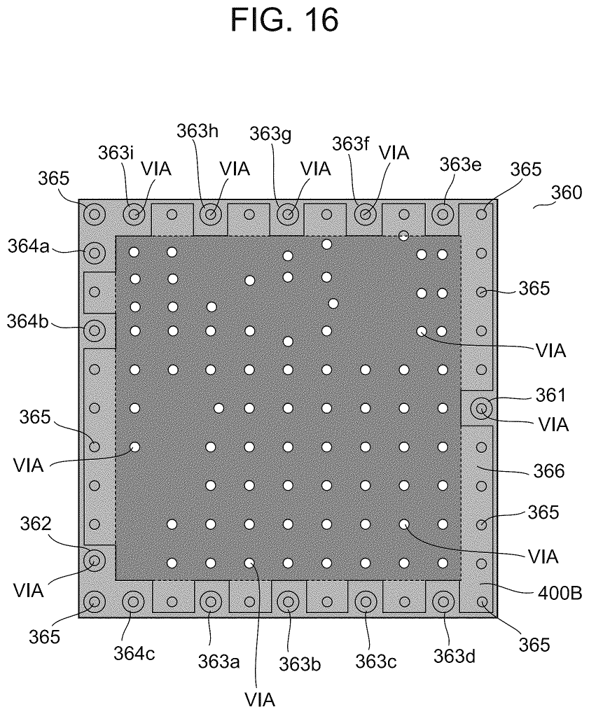

As illustrated in FIG. 16, the sixth-layer pattern 360 is a pattern on the back surface of the third substrate 300, and is a pad layer connected to the front side pad of the first substrate 100 by the solder balls 50.

The sixth-layer pattern 360 includes the input pad 361, the output pad 362, the bias pads 363a to 363i, the bias pads 364a to 364c, and the ground pad 365 at positions facing the input pad 121a, the output pad 122a, the bias pads 123aa to 123ia, the bias pads 124aa to 124ca, and the ground pad 125a, which are formed on the front surface of the first substrate 100, respectively, along the four sides.

Further, the sixth-layer pattern 360 includes a ground layer 366 which is a solid pattern electrically insulated from the input pad 361, the output pad 362, the bias pads 363a to 363i, and the bias pads 364a to 364c in a region excluding these pads.

In FIG. 16, the ground layer 366 is electrically connected to the ground layer located in the upper layer by a via VIA indicated by circle marks “∘” in the ground layer 366.

Note that, in the ground layer 366, a portion connected to the vias VIA located along the four sides also serves as the ground pad 365. However, the vias VIA do not serve as the ground pads 365 at positions facing the plurality of front side pads in the first substrate 100.

The input pad 361 is connected to the via VIA connected to the input pad 311 in the first-layer pattern 310.

The output pad 362 is connected to the via VIA connected to the other end 321b of the first line 321 in the second-layer pattern 320.

The bias pads 363a to 363e are connected to the vias VIA connected to the bias pads 313a to 313e in the first-layer pattern 310.

The bias pad 363f is connected to the via VIA connected to the other end 351b of the fourth line 351 in the fifth-layer pattern 350.

The bias pad 363g is connected to the via VIA connected to the other end 322b of the second line 322 in the second-layer pattern 320.

The bias pad 363h is connected to the via VIA connected to the other end 352b of the fifth line 352 in the fifth-layer pattern 350.

The bias pad 363i is connected to the via VIA connected to the other end 323b of the third line 323 in the second-layer pattern 320.

The bias pads 364a to 364c are connected to the vias VIA connected to the bias pads 314a to 314c in the first-layer pattern 310.

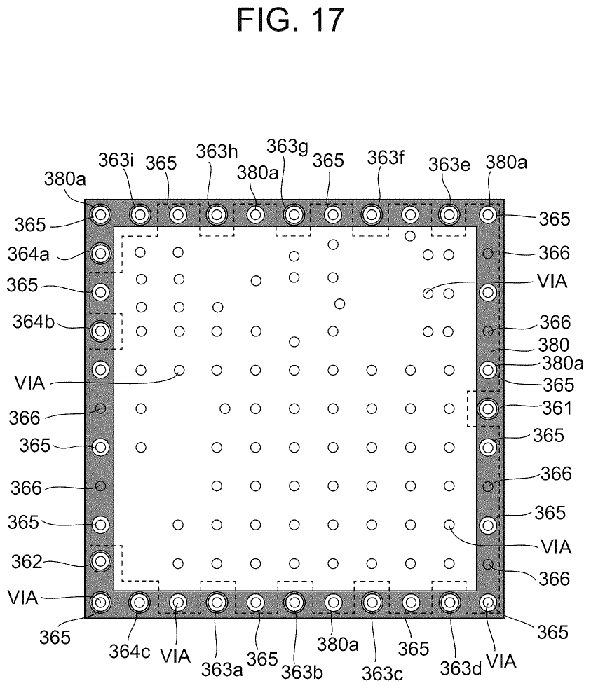

A resist film 380 is formed on the front surface of the sixth-layer pattern 360, and as illustrated in FIG. 17, has a circular opening 380a for exposing the front surfaces of the input pad 361, the output pad 362, the bias pads 363a to 363i, the bias pads 364a to 364c, and the ground pad 365 and mounting the solder ball 50.

Note that, in FIG. 17, the resist film 380 covers the front surface at positions indicated by circle marks “∘” denoted by reference numeral 366, that is, positions facing the one input pad 103a, the other input pad 104a, the bias pad 109a, the output pad 110a, the bias pad 111a, and the bias pad 112a in the first substrate 100.

As illustrated in FIGS. 12 and 15, the first line 321 to the third line 323 in the second-layer pattern 320 and the fourth line 351 and the fifth line 352 in the fifth-layer pattern 350 each include at least one bent portion instead of a straight line in such a manner that the first line 321 to the third line 323 do not structurally and electrically interfere with the fourth line 351 and the fifth line 352.

In the third substrate 300, as described above, in the first-layer pattern 310 and the sixth-layer pattern 360 serving as pad layers, regions other than the pads excluding the ground pads are set as the ground layers 315 and 366.

In the third substrate 300, in the second-layer pattern 320 and the fifth-layer pattern 350 to be wiring layers, a region excluding vias VIA connected to pads excluding lines and ground pads is set as a ground layer.

In the third substrate 300, in the third-layer pattern and the fourth-layer pattern, regions other than the vias VIA connected to the pads excluding the ground pads are set as the ground layers 331 and 341.

In the third substrate 300, since the first-layer pattern 310 to the sixth-layer pattern 360 are configured as described above, it is possible to suppress unnecessary coupling between the first semiconductor element 10 mounted on the first substrate 100 and the second semiconductor element 20 and the third semiconductor element 30 mounted on the second substrate 200, and unnecessary coupling between the first line 321 and the third line 323 in the second-layer pattern 320 and between the fourth line 351 and the fifth line 352 in the fifth-layer pattern 350, and further, it is possible to perform wiring using necessary lines without increasing the size in the plane direction of the third substrate 300, and it is possible to miniaturize the semiconductor device itself.

As illustrated in FIG. 1, the first resin layer 400 is a resin sealing material that is in contact with the periphery of the front surface of the first substrate 100 and the periphery of the back surface of the third substrate 300 in such a manner as to have a hollow portion 400C and hermetically seals the hollow portion 400C.

The resin sealing material only needs to have an insulating function, and for example, a resin material such as a silicon-based resin material or an epoxy-based resin material may be selected as necessary.

As illustrated in FIG. 2, the first resin layer 400 is bonded to a resin bonding surface 400A around the front surface of the first substrate 100.

The resin bonding surface 400A of the first substrate 100 is equivalent to a region corresponding to four sides of the resist film 60 applied to the front surface of the first dielectric substrate 101 of the first substrate 100 illustrated in FIG. 4.

Therefore, as understood from FIG. 2, the first resin layer 400 does not overlap with the first wiring pattern layer constituting the transmission lines and the like formed on the front surfaces of the first semiconductor element 10 and the first dielectric substrate 101.

The expression that the first resin layer 400 does not overlap with the first wiring pattern layer does not only mean that the first resin layer 400 does not completely overlap with the first wiring pattern layer, but also includes a range that the first resin layer 400 may somewhat overlap therewith as long as the impedance for the lines constituting the first wiring pattern layer falls within the range of design tolerance.

The first resin layer 400 is formed so as not to overlap with at least the first semiconductor element 10 and the first transmission line 106 to the third transmission line 108.

As illustrated in FIG. 16, the first resin layer 400 is bonded to a resin bonding surface 400B around the back surface of the third substrate 300.

The resin bonding surface 400B of the third substrate 300 is a region facing the resin bonding surface 400A in the first substrate 100.

The first resin layer 400 has a rectangular frame structure having the rectangular hollow portion 400C that is a hermetically sealed space between the front surface of the first substrate 100 and the back surface of the third substrate 300.

Therefore, since the first semiconductor element 10 is mounted in the hermetically sealed hollow portion 400C, the first semiconductor element 10 is shielded from the outside air, and environmental resistance to the first semiconductor element 10 is improved. That is, it is possible to reduce the influence of high humidity and high temperature air, which are causes of degradation as an amplifier in the case of an amplifier.

Moreover, although the first resin layer 400 having a large relative permittivity with respect to the relative permittivity 1 of air, for example, 3 is used, the first resin layer 400 does not overlap with the first semiconductor element 10 and the first wiring pattern layer formed on the front surface of the first dielectric substrate 101, and thus, in the amplifier constituting the semiconductor device according to the first embodiment, there is no concern about a decrease in gain and efficiency as an amplifier due to a change in characteristic impedance due to the influence of wavelength shortening and an increase in dielectric loss due to a dielectric loss tangent, and ultra-wideband characteristics of the amplifier can also be maintained.

Furthermore, since the first resin layer 400 functions as a kind of adhesive between the first substrate 100 and the third substrate 300, a bonding area between the first substrate 100 and the third substrate 300 is widened, and the substrates are in a reinforced state even when there is external vibration and impact, so that impact resistance is also improved.

As illustrated in FIG. 1, the second resin layer 500 is a resin sealing material that is in contact with the periphery of the front surface of the second substrate 200 and the periphery of the front surface of the third substrate 300 in such a manner as to have a hollow portion 500C and hermetically seals the hollow portion 500C.

The resin sealing material only needs to have an insulating function, and for example, a resin material such as a silicon-based resin material or an epoxy-based resin material may be selected as necessary.

As illustrated in FIG. 6, the second resin layer 500 is bonded to a resin bonding surface 500A around the front surface of the second substrate 200.

The resin bonding surface 500A around the front surface of the second substrate 200 is equivalent to a region corresponding to four sides of the resist film 80 applied to the front surface of the second dielectric substrate 201 in the second substrate 200 illustrated in FIG. 8.

Therefore, as understood from FIG. 6, the second resin layer 500 does not overlap with the second wiring pattern layer constituting the lines formed on the front surfaces of the second semiconductor element 20, the third semiconductor element 30, and the second dielectric substrate 201.

The expression that the second resin layer 500 does not overlap with the second wiring pattern layer does not only mean that the second resin layer 500 does not completely overlap with the second wiring pattern layer, but also includes a range that the second resin layer 500 may somewhat overlap therewith as long as the impedance for the lines constituting the second wiring pattern layer falls within the range of design tolerance.

As illustrated in FIG. 10, the second resin layer 500 is bonded to the resin bonding surface 500B around the front surface of the third substrate 300.

The resin bonding surface 500B of the third substrate 300 is a region facing the resin bonding surface 500A of the second substrate 200.

The second resin layer 500 has a rectangular frame structure having the rectangular hollow portion 500C that is a hermetically sealed space between the front surface of the second substrate 200 and the front surface of the third substrate 300.

Therefore, since the second semiconductor element 20 and the third semiconductor element 30 are mounted in the hermetically sealed hollow portion 500C, the second semiconductor element 20 and the third semiconductor element 30 are shielded from the outside air, and environmental resistance to the second semiconductor element 20 and the third semiconductor element 30 is improved. That is, it is possible to reduce the influence of high humidity and high temperature air, which are causes of degradation as an amplifier in the case of an amplifier.

Moreover, although the second resin layer 500 having a large relative permittivity with respect to the relative permittivity 1 of air, for example, 3 is used, the second resin layer 500 does not overlap with the second wiring pattern layer formed on the front surfaces of the second semiconductor element 20, the third semiconductor element 30, and the second dielectric substrate 201, and thus, in the amplifier constituting the semiconductor device according to the first embodiment, there is no concern about a decrease in gain and efficiency as an amplifier due to a change in characteristic impedance due to the influence of wavelength shortening and an increase in dielectric loss due to a dielectric loss tangent, and ultra-wideband characteristics of the amplifier can also be maintained.

Further, since the second resin layer 500 functions as a kind of adhesive between the second substrate 200 and the third substrate 300, a bonding area between the second substrate 200 and the third substrate 300 is widened, and the substrates are in a reinforced state even when there is external vibration and impact, so that impact resistance is also improved.

Note that in a semiconductor device of a type in which the second substrate 200 is directly stacked on the first substrate 100, the resin layer is formed in direct close contact with the resin bonding surface 400A around the front surface of the first substrate 100 and the resin bonding surface 500A around the front surface of the second substrate 200.

As a result, a hollow portion hermetically sealed by the resin layer is formed, and the first semiconductor element 10, the second semiconductor element 20, and the third semiconductor element 30 mounted in the hollow portion are shielded from the outside air, and have excellent environmental resistance and excellent impact resistance as a semiconductor device.

Next, assembly of the semiconductor device according to the first embodiment will be described.

First, the first substrate 100 on which the first semiconductor element 10 is mounted, the second substrate 200 on which the second semiconductor element 20 and the third semiconductor element 30 are mounted, and the third substrate 300 which is an interposer substrate disposed between the first dielectric substrate and the second dielectric substrate to face each other are prepared.

This step is a step of preparing the first substrate 100, the second substrate 200, and the third substrate 300.

The first substrate 100 is completed as the first substrate 100 in which the first semiconductor element 10 is mounted in the first opening 102 of the first dielectric substrate 101, the first wiring pattern layer and the first front side pads are formed on the front surface of the first dielectric substrate 101, a necessary chip component is mounted on the front surface of the first dielectric substrate 101, wire bonding between the first semiconductor element 10 and the first wiring pattern layer is finished, and the first ground conductor 130 is formed on the back surface of the first dielectric substrate 101.

The second substrate 200 is completed as the second substrate 200 in which the second semiconductor element 20 and third semiconductor element 30 are mounted in the second opening 202 of the second dielectric substrate 201, the second wiring pattern layer and the second front side pads are formed on the front surface of the second dielectric substrate 201, a necessary chip component is mounted on the front surface of the second dielectric substrate 201, wire bonding between the second semiconductor element 20 and the third semiconductor element 30 and the second wiring pattern layer is finished, and the second ground conductor 230 is formed on the back surface of the second dielectric substrate 201.

The third substrate 300 is completed as an interposer substrate having a multilayer structure in which the third back side pads are formed around the back surface, the third front side pads are formed around the front surface, and electrical connection between the first substrate 100 and the second substrate 200 is relayed.

The plurality of first front side pads whose front surface is exposed through the opening 60a in the resist film 60 in the first substrate 100 and the plurality of third back side pads whose front surface is exposed through the opening 380a in the resist film 380 in the third substrate 300 are brought into a state where their respective corresponding pads face each other.

The solder balls 50 are arranged between the first substrate 100 and the third substrate 300.

In this manner, the back surface of the third substrate 300 is in a state of facing the front surface of the first substrate 100, and then the third substrate 300 is mounted on the first substrate 100.

This step is a step of mounting the third substrate 300 on the first substrate 100 via the solder balls 50.

The plurality of third front side pads whose front surface is exposed through the opening 370a in the resist film 370 in the third substrate 300 and the plurality of second front side pads whose front surface is exposed through the opening 80a in the resist film 80 in the second substrate 200 are brought into a state where their respective corresponding pads face each other.

The solder balls 70 are arranged between the third substrate 300 and the second substrate 200.

In this manner, the front surface of the second substrate 200 faces the front surface of the third substrate 300, and then the second substrate 200 is mounted on the third substrate 300.

This step is a step of mounting the second substrate 200 on the third substrate 300 via the solder balls 70.

In this manner, in a state where the third substrate 300 and the second substrate 200 are stacked on the front surface of the first substrate 100, the solder balls 50 and the solder balls 70 are heated in such a manner as to be melted by, for example, solder reflow. Further, pressure bonding is performed from the second substrate 200 side in accordance with manufacturing accuracy.

When the solder balls 50 and the solder balls 70 are melted, the corresponding pads are bonded to each other, the corresponding pads are electrically connected to each other, the third substrate 300 is mounted and fixed on the first substrate 100, and the second substrate 200 is mounted and fixed on the third substrate 300.

This step is a step of manufacturing a stack in which the third substrate 300 is stacked on the first substrate 100 and the second substrate 200 is stacked on the third substrate 300.

Next, in the stack, as illustrated in FIG. 1, a resin sealing material is partially injected from a side face of the stack along the entire periphery between the first substrate 100 and the third substrate 300 to form the first resin layer 400. This step is a step of forming the first resin layer 400.

The periphery of the front surface of the first substrate 100 and the periphery of the back surface of the third substrate 300 are also bonded by the first resin layer 400.

The injection depth at the time of forming the first resin layer 400 is a region corresponding to four sides of the resist film 60 applied to the front surface of the first dielectric substrate 101 in the first substrate 100 illustrated in FIG. 4.

The first resin layer 400 is configured not to overlap with the first wiring pattern layer constituting the transmission lines and the like formed on the front surfaces of the first semiconductor element 10 and the first dielectric substrate 101.

In this manner, since the first resin layer 400 is formed only around the four sides of the first dielectric substrate 101 in the first substrate 100, most of the space between the first substrate 100 and the third substrate 300 is in a hollow state. That is, the hermetically sealed rectangular hollow portion 400C surrounded by the first resin layer 400 is formed between the first substrate 100 and the third substrate 300.

Similarly, as illustrated in FIG. 1, a resin sealing material is partially injected from a side face of the stack along the entire periphery between the second substrate 200 and the third substrate 300 to form the second resin layer 500.

This step is a step of forming the second resin layer 500.

The periphery of the front surface of the second substrate 200 and the periphery of the front surface of the third substrate 300 are also bonded by the second resin layer 500.

The injection depth at the time of forming the second resin layer 500 is a region corresponding to four sides of the resist film 80 applied to the front surface of the second dielectric substrate 201 in the second substrate 200 illustrated in FIG. 8.

The second resin layer 500 is configured not to overlap with the second wiring pattern layers formed on the front surfaces of the second semiconductor element 20, the third semiconductor element 30, and the second dielectric substrate 201.

In this manner, since the second resin layer 500 is formed only around the four sides of the second dielectric substrate 201 in the second substrate 200, most of the space between the second substrate 200 and the third substrate 300 is in a hollow state.

That is, the hermetically sealed rectangular hollow portion 500C surrounded by the second resin layer 500 is formed between the second substrate 200 and the third substrate 300.

As described above, assembly as a semiconductor device in which the third substrate 300 is stacked on the first substrate 100 and the second substrate 200 is stacked on the third substrate 300, that is, manufacturing of the semiconductor device is completed.

Note that a semiconductor device of a type in which the second substrate 200 is directly stacked on the first substrate 100 is assembled and manufactured as follows.

The plurality of first front side pads whose front surface is exposed through the opening 60a in the resist film 60 in the first substrate 100 and the plurality of second front side pads whose front surface is exposed through the opening 80a in the resist film 80 in the second substrate 200 are brought into a state where their respective corresponding pads face each other.

Solder balls are arranged between the first substrate 100 and the second substrate 200, and the second substrate 200 is mounted on the first substrate 100.

Next, the solder balls are melted to bond the pads to each other.

In this state, a resin sealing material is partially injected along the entire periphery between the first substrate 100 and the second substrate 200 to form a resin layer, thereby completing assembly and manufacture as a semiconductor device.

In the assembly and manufacture of the semiconductor device according to the first embodiment, when the solder balls 50 and the solder balls 70 are heated during melting, the first substrate 100, the second substrate 200, and the third substrate 300 are thermally expanded.

However, since the first substrate 100 and the second substrate 200 are arranged on the upper and lower sides, warpage of the first substrate 100, the second substrate 200, and the third substrate 300 that occurs at the time of assembly is reduced, improvement of yield as a semiconductor device and stability of performance can be compensated, and reliability as a semiconductor device is improved.

In addition, since the resin sealing material is injected from the side face of the stack into the space between the front surface of the first substrate 100 and the back surface of the third substrate 300 to form the first resin layer 400 and provide the hermetically sealed hollow portion 400C, and the resin sealing material is injected from the side face of the stack into the space between the front surface of the second substrate 200 and the front surface of the third substrate 300 to form the second resin layer 500 and provide the hermetically sealed hollow portion 500C, it is possible to block the first semiconductor element 10, the second semiconductor element 20, and the third semiconductor element 30 from the outside air, and it is possible to reduce the influence of high humidity and high temperature air that cause deterioration as an amplifier constituting the semiconductor device according to the first embodiment.

Moreover, although the first resin layer 400 and the second resin layer 500 having a large relative permittivity with respect to the relative permittivity 1 of air are used, the hollow portion 400C and the hollow portion 500C are formed, and thus, in the amplifier constituting the semiconductor device according to the first embodiment, with the first resin layer 400 and the second resin layer 500, there is no concern about a decrease in gain and efficiency as an amplifier due to a change in characteristic impedance due to the influence of wavelength shortening and an increase in dielectric loss due to a dielectric loss tangent, and ultra-wideband characteristics of the amplifier can also be maintained.

In addition, since the first resin layer 400 fills the periphery of the solder balls 50, the bonding area between the front surface of the first substrate 100 and the front surface of the third substrate 300 is increased, and since the second resin layer 500 fills the periphery of the solder balls 70, the bonding area between the front surface of the second substrate 200 and the front surface of the third substrate 300 is increased, and the substrates are in a reinforced state even when there is external vibration and impact, so that impact resistance is also improved.

Here, each signal path will be described. Here, the semiconductor device according to the present first embodiment will be described as being mounted on a mounting substrate including, for example, a resin substrate.

High-frequency input signals to the input terminals 11 and 12 of the first semiconductor element 10 are supplied from the mounting substrate to the input terminals 11 and 12 via the input pads 103b and 104b—the vias VIA—the input pads 103a and 104a—the input lines 103 and 104 in the first substrate 100.

The high-frequency amplified signal output from the output terminals 13 and 14 of the first semiconductor element 10 is transmitted through the first transmission line 106, the second transmission line 107, and the third transmission line 108 in the first substrate 100, and is output from the output branch portion 105a of the output combining circuit 105 to the mounting substrate via the output line 110—the output pad 110a—the via VIA—the output pad 110b.

A bias current to each of the bias terminals 15 and 16 of the first semiconductor element 10 is supplied from the mounting substrate to the bias terminals 15 and 16 via the bias pads 111b and 112b—the via VIA—the bias pads 111a and 112a—the bias lines 111 and 112 in the first substrate 100.

A bias current to the output branch portion 105a of the output combining circuit 105 is supplied from the mounting substrate to the output branch portion 105a via the bias pad 109b—the via VIA—the bias pad 109a—the bias line 109 in the first substrate 100.

An input signal to each of the input terminals 31 of the third semiconductor element 30 is supplied from the mounting substrate to the input terminal 31 via the input pad 121b—the via VIA—the input pad 121—the solder ball 50 on the first substrate 100, via the input pad 361—the via VIA—the input pad 311—the solder ball 70 on the third substrate 300, and via the input pad 203a—the input line 203 on the second substrate 200.

Output signals output from the output terminals 32 and 33 of the second semiconductor element 20 are output to the mounting substrate via the output line 204—the output pad 204a—the solder ball 70 on the second substrate 200, via the output pad 312—the via VIA—the first line 321—the via VIA—the output pad 362—the solder ball 50 on the third substrate 300, and via the output pad 122a—the via VIA—the output pad on the first substrate 100.

A bias current to each of the bias terminals 24a to 24c of the second semiconductor element 20 is supplied from the mounting substrate to the bias terminals 24a to 24c via the bias pads 124ab to 124cb—the via VIA—the bias pads 124aa to 124ca—the solder balls 50 on the first substrate 100, via the bias pads 364a to 364c—the via VIA—the bias pads 314a to 314c—the solder balls 70 on the third substrate 300, and via the bias pads 206aa to 206ac—the bias lines 206a to 206c on the second substrate 200.

A bias current to each of the bias terminals 34a to 34e of the third semiconductor element 30 is supplied from the mounting substrate to the bias terminals 34a to 34e via the bias pads 123ab to 123eb—the via VIA, the bias pads 123aa to 123ea—the solder balls 50 on the first substrate 100, via the bias pads 363a to 363e—the via VIA—the bias pads 313a to 313e—the solder balls 70 on the third substrate 300, and via the bias pads 205aa to 205ea—the bias lines 205a to 205e on the second substrate 200.

A bias current to the bias terminal 34f of the third semiconductor element 30 is supplied from the mounting substrate to the bias terminal 34f via a bias pad 123fb—the via VIA-a bias pad 123fa—the solder ball 50 on the first substrate 100, via the bias pad 363f—the via VIA—the fourth line 351—the via VIA—the bias pad 313f—the solder ball 70 on the third substrate 300, and via the bias pad 205fa—the bias line 205f on the second substrate 200.

A bias current to the bias terminal 34g of the third semiconductor element 30 is supplied from the mounting substrate to the bias terminal 34g via a bias pad 123gb—the via VIA-a bias pad 123ga—the solder ball 50 on the first substrate 100, via the bias pad 363g—the via VIA—the second line 322—the via VIA—the bias pad 313g—the solder ball 70 on the third substrate 300, and via the bias pad 205ga—the bias line 205g on the second substrate 200.

A bias current to the bias terminal 34h of the third semiconductor element 30 is supplied from the mounting substrate to the bias terminal 34g via a bias pad 123hb—the via VIA-a bias pad 123ha—the solder ball 50 on the first substrate 100, via the bias pad 363h—the via VIA—the fifth line 352—the via VIA—the bias pad 313g—the solder ball 70 on the third substrate 300, and via the bias pad 205ga—the bias line 205g on the second substrate 200.

A bias current to the bias terminal 34i of the third semiconductor element 30 is supplied from the mounting substrate to the bias terminal 34g via the bias pad 123ib—the via VIA—the bias pad 123ia—the solder ball 50 on the first substrate 100, via the bias pad 363i—the via VIA—the third line 323—the via VIA—the bias pad 313i—the solder ball 70 on the third substrate 300, and via the bias pad 205ia—the bias line 205i on the second substrate 200.

As described above, the semiconductor device according to the first embodiment has the following configuration.

That is, the first substrate 100 and the second substrate 200 are stacked in such a manner as to sandwich the third substrate 300. The first ground conductor 130 and the second ground conductor 230 constituted by thick copper are formed on the back surfaces of the first substrate 100 and the second substrate 200, respectively. The first semiconductor element 10 is mounted and fixed on the front surface of the first ground conductor 130 with the first heat sink 10A interposed therebetween in the first opening 102 reaching the front surface of the first ground conductor 130, and the second semiconductor element 20 is similarly mounted and fixed on the front surface of the second ground conductor 230 with the second heat sink 20A interposed therebetween in the second opening 202 reaching the front surface of the second ground conductor 230.

Thus, diffusibility with respect to heat generated by the first semiconductor element 10 and the second semiconductor element 20 by the first ground conductor 130 and the second ground conductor 230 is good, and heat dissipation as a semiconductor device is improved.

Further, the semiconductor device according to the first embodiment performs heating in order to use the solder balls 50 and the solder balls 70 which are conductive materials in assembling the first substrate 100, the second substrate 200, and the third substrate 300.

Thus, thermal expansion occurs in each of the first substrate 100, the second substrate 200, and the third substrate 300.

However, in the semiconductor device according to the first embodiment, the first substrate 100 and the second substrate 200 are formed of the same material, and are arranged vertically to form a stack.

Therefore, the thermal expansion coefficients of the first substrate 100, the second substrate 200, and the third substrate 300 are approximately the same, so that improvement in yield and stability of performance as a semiconductor device can be compensated, and reliability as a semiconductor device is improved.

In addition, since the semiconductor device according to the first embodiment includes, in the first wiring pattern layer in the first substrate 100, the output combining circuit 105 having the first transmission line 106 and the second transmission line 107 connected in series between the output branch portion 105a and the one output terminal 13 of the first semiconductor element 10, and the third transmission line 108 connected between the output branch portion 105a and the other output terminal 14 of the first semiconductor element 10, it is possible to achieve, as a semiconductor device, ultra-wideband characteristics without using an extra matching circuit.

In the semiconductor device according to the first embodiment, since the output combining circuit 105 can be formed as a wiring pattern on the front surface of the first substrate 100, the influence of unnecessary parasitic components can be reduced, and ultra-wideband characteristics can be achieved more easily.

Further, in the semiconductor device according to the first embodiment, since the third substrate 300 includes the ground layer 315 and the ground layer 366 which are solid patterns on the front surface and the back surface, respectively, the ground layers 315 and 366 function as conductive shields, so that unnecessary coupling between the first semiconductor element 10, the second semiconductor element 20, and the third semiconductor element 30 can be suppressed.

In the semiconductor device according to the first embodiment, since the various wirings of the third substrate 300 are configured using the second-layer pattern 320 to the fifth-layer pattern 350 which are the inner-layer wirings of the third substrate 300, it is possible to suppress coupling between these various wirings and various wirings formed on the first substrate 100 and the second substrate 200.

In the semiconductor device according to the first embodiment, since the first substrate 100 and the second substrate 200 can be formed into a stacked package as a stacked structure in such a manner as to sandwich the third substrate 300, reliability as a circuit is improved.

Further, in the semiconductor device according to the first embodiment, by utilizing the inner layer wiring of the third substrate 300, a part of the wiring that needs to be formed on the first substrate 100 and the second substrate 200 can be wired in the inner layer of the third substrate 300, so that necessary wiring can be performed without increasing the size in the plane direction as the semiconductor device, and the semiconductor device itself can be downsized.

In addition, since the semiconductor device according to the first embodiment is provided with the first resin layer 400 between the periphery of the front surface of the first substrate 100 and the periphery of the back surface of the third substrate 300, the semiconductor device has the hollow portion 400C hermetically sealed by four side portions of the periphery of the front surface of the first substrate 100 and the periphery of the back surface of the third substrate 300, so that environmental resistance to the first semiconductor element 10 is improved.

Moreover, even when there is external vibration and impact, the structure is reinforced by the first resin layer 400, so that impact resistance is also improved.

In addition, since the semiconductor device according to the first embodiment is provided with the second resin layer 500 between the periphery of the front surface of the second substrate 200 and the periphery of the front surface of the third substrate 300, the semiconductor device has the hollow portion 500C hermetically sealed by four side portions of the periphery of the front surface of the second substrate 200 and the periphery of the front surface of the third substrate 300, so that environmental resistance to the second semiconductor element 20 and the third semiconductor element 30 is improved.

Moreover, the structure is reinforced by the second resin layer 500 even when there is external vibration and impact, so that impact resistance is also improved.

In the semiconductor device according to the first embodiment, the first substrate 100, the second substrate 200, and the third substrate 300 are stacked using the solder balls 50 and the solder balls 70 to be assembled into a stack, and then, in a subsequent step, a resin sealing material is injected only in the vicinity of the mounting portions of the solder balls 50 and the solder balls 70 to form the first resin layer 400 and the second resin layer 500.

As a result, a resin sealing material for forming the first resin layer 400 and the second resin layer 500 is not applied to the first wiring pattern layer and the second wiring pattern layer including the first semiconductor element 10, the second semiconductor element 20, and the third semiconductor element 30 and various lines necessary for implementing the ultra-wideband characteristics of the amplifier such as the transmission line 106 having a high impedance and a long electrical length, and the hollow portion 400C and the hollow portion 500C can be formed inside the first resin layer 400 and the second resin layer 500 having a rectangular frame structure.

Therefore, in the amplifier constituting the semiconductor device according to the first embodiment, the influence of wavelength shortening due to the relative permittivity of the resin sealing material as the first resin layer 400 and the second resin layer 500 and the influence of an increase in dielectric loss are reduced, and a stable operation as an amplifier can be implemented even in a high humidity and high temperature environment while maintaining the characteristics of the amplifier.

In addition, in the semiconductor device according to the first embodiment, after being assembled as a stack, the resin sealing material is injected only into the vicinity of the mounting portions of the solder balls 50 and the solder balls 70 in a post-process to form the first resin layer 400 and the second resin layer 500, and thus, as compared with a stack assembled using only the solder balls 50 and the solder balls 70, a bonding area between the first substrate 100 and the third substrate 300 and a bonding area between the second substrate 200 and the third substrate 300 are increased, so that the semiconductor device is strengthened against impact such as external vibration, and impact resistance as a semiconductor device is improved.

Note that, although the first semiconductor element 10 is mounted on the first substrate 100 in the semiconductor device according to the first embodiment, another semiconductor element may be mounted as necessary.

Further, although the second semiconductor element 20 and the third semiconductor element 30 are mounted on the second substrate 200, other semiconductor elements may be further mounted as necessary.

Further, in the semiconductor device according to the first embodiment, some of the transmission lines from the first transmission line 106 to the third transmission line 108 constituting the output combining circuit 105 formed on the front surface of the first dielectric substrate 101 in the first substrate 100 may be formed on the third substrate 300.

Further, in the semiconductor device according to the first embodiment, the wiring path by lines in the third substrate 300 is a wiring path by lines for both the second semiconductor element 20 and the third semiconductor element 30, but the wiring path may be a wiring path by lines for either one of the second semiconductor element 20 and the third semiconductor element 30.

In addition, in the semiconductor device according to the first embodiment, as the insulating material constituting the first dielectric substrate 101 in the first substrate 100, the second dielectric substrate 201 in the second substrate 200, and the third substrate 300, it is sufficient if a material such as resin or ceramic is selected according to the application.

By selecting a resin as the insulating material, a relatively inexpensive semiconductor device can be obtained.

By selecting ceramic as the insulating material, it is possible to form a highly accurate pattern and to obtain an effect of improving heat dissipation, and the like.

When the same material is used as an insulating material constituting the first dielectric substrate 101 in the first substrate 100, the second dielectric substrate 201 in the second substrate 200, and the third substrate 300, reliability is improved.

### Second Embodiment

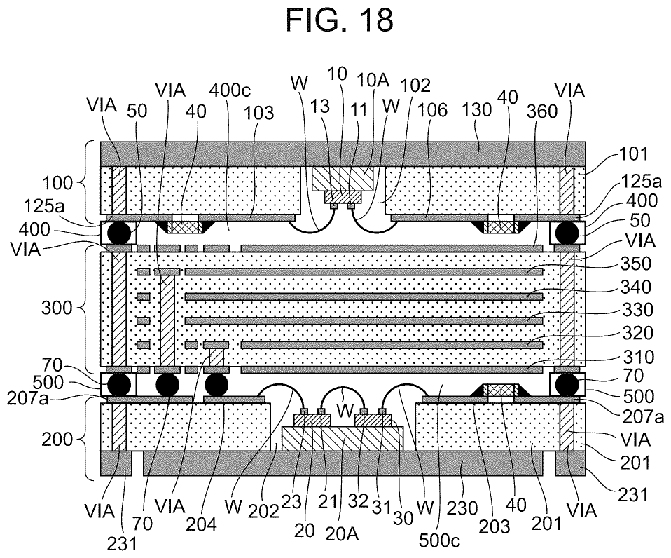

A semiconductor device according to a second embodiment will be described with reference to FIG. 18.

The semiconductor device according to the second embodiment is different from the semiconductor device according to the first embodiment in that the semiconductor device according to the first embodiment has a structure in which the first substrate 100 is mounted and fixed on the mounting substrate and the third substrate 300 and the second substrate 200 are stacked in this order, whereas the semiconductor device according to the second embodiment has a structure in which the second substrate 200 is mounted and fixed on the mounting substrate and the third substrate 300 and the first substrate 100 are stacked in this order.

The basic configurations of the first substrate 100, the second substrate 200, and the third substrate 300 in the semiconductor device according to the second embodiment are the same as those of the first substrate 100, the second substrate 200, and the third substrate 300 in the semiconductor device according to the first embodiment, and thus differences will be mainly described.

Note that, in FIG. 18, the same reference numerals as those attached in FIG. 1 denote the same or corresponding parts.

The first substrate 100 does not include the plurality of the first back side pads 131 in the first embodiment, and includes a first ground conductor 130 formed by patterning a conductor that is a thick copper foil having a thickness of 100 um or more, in the present second embodiment, 200 um on the entire back surface of the first dielectric substrate 101.

The first ground conductor 130 is connected to a ground pad 125a formed on the front surface of the first dielectric substrate 101 via a via VIA.

By forming the first ground conductor 130 on the entire back surface of the first dielectric substrate 101, the heat dissipation area can be expanded with respect to the first semiconductor element 10 having a large amount of heat generation.

The first substrate 100 is not provided with the vias VIA illustrated in the first embodiment for the first front side pads other than the ground pad 125a.

The other configurations of the first substrate 100 are the same as those of the first substrate 100 in the first embodiment.

The second substrate 200 has a plurality of second back side pads 231 formed by patterning a conductor that is a thick copper foil simultaneously with the second ground conductor 230 along four sides of the back surface of the second dielectric substrate 201.

The plurality of second back side pads 231 is pads corresponding to the plurality of first back side pads 131 on the first substrate 100 in the first embodiment.

That is, the plurality of second back side pads 231 is formed by pads corresponding to the one input pad 103b, the other input pad 104b, the output-side bias pad 109b, the output pad 110b, the one input-side bias pad 111b, the other input-side bias pad 112b, the ground pad 113b, the input pad 121b, the output pad 122b, the bias pads 123ab to 123ib, the bias pads 124ab to 124cb, and the ground pad 125a of pads other than them, which are the plurality of first back side pads 131 in the first substrate 100, are formed in the same arrangement along four sides of the back surface of the second dielectric substrate 201.

Further, in the second substrate 200, a plurality of second front side pads is formed along four sides of the front surface of the second dielectric substrate 201 in such a manner as to correspond to the plurality of second back side pads 231, and electrically connect the plurality of second back side pads 231 and the corresponding plurality of second front side pads by the vias VIA.

On the second substrate 200, among the second front side pads formed on the front surface of the second dielectric substrate 201, the front surfaces of the input pad 203a, the bias pads 205aa to 205ea on the input side, and the bias pads 206aa to 206ac on the output side are covered with the resist film 80, the front surfaces of the plurality of other second front side pads is exposed through the circular opening 80a of the resist film 80, and the solder ball 70 is mounted.

Other configurations of the second substrate 200 are the same as those of the second substrate 200 in the first embodiment.

As illustrated in FIG. 18, the third substrate 300 is an interposer substrate having a multilayer structure that is arranged between the second substrate 200 and the first substrate 100 in such a manner as to face the first substrate 100 and the second substrate 200, has a plurality of third front side pads on the front surface, each of which is connected to a plurality of second front side pads of the second substrate 200 by the solder balls 70, and has a plurality of third back side pads on the back surface, each of which is connected to a plurality of first front side pads of the first substrate 100 by the solder balls 50.

The third substrate 300 is a substrate that relays electrical connection between a front side pad arranged in the central portion of the second substrate 200, in the present second embodiment, the output pad 204a and each of the bias pads 205fa to 205ia, and a second front side pad arranged at the side portion of the second substrate 200, in the present second embodiment, a front side pad (hereinafter referred to as output pads 222 and bias pads 223f to 223i for distinction) corresponding to the output pad 122b and each of the bias pads 123fb to 123ib of the first substrate 100.

The third substrate 300 is an interposer substrate having a six-layer structure in the present second embodiment.

The front surface side of the third substrate 300, that is, the lowermost layer will be described as the first layer, and the back surface side, that is, the uppermost layer will be described as the sixth layer.

In the following description, each layer pattern is similar to each layer pattern in the first embodiment, and thus will be described without using the drawings. Note that reference numerals are given for distinction.

The first-layer pattern 310 is a pattern on the front surface of the third substrate 300, and is a pad layer connected to the front side pad of the second substrate 200 by the solder balls 70.

The first-layer pattern 310 includes pads corresponding to the front side pads formed on the front surface of the second substrate 200 and the ground layer 315 that is a solid pattern, similarly to the first-layer pattern 310 in the first embodiment.

The second-layer pattern 320 includes the first line 321, the second line 322, the third line 323, and the ground layer 324 that is a solid pattern, similarly to the second-layer pattern 320 in the first embodiment.

In the first line 321, one end is connected to the via VIA connected to the output pad 312 arranged in the central portion of the first-layer pattern 310, and the other end is connected to the via VIA connected to the output pad 362 arranged at the side portion of the sixth-layer pattern.

In the second line 322, one end is connected to the via VIA connected to the bias pad 313g arranged in the central portion of the first-layer pattern 310, and the other end is connected to the via VIA connected to the bias pad 363g arranged at the side portion of the sixth-layer pattern.

In the third line 323, one end is connected to the via VIA connected to the bias pad 313i arranged in the central portion of the first-layer pattern 310, and the other end is connected to the via VIA connected to the bias pad 363i in the sixth-layer pattern arranged at the side portion.

The third-layer pattern 330 and the fourth-layer pattern 340 are the same as the third-layer pattern 330 and the fourth-layer pattern 340 in the first embodiment, and are the ground layer 331 and the ground layer 341 which are solid patterns, respectively.

The fifth-layer pattern 350 includes the fourth line 351, the fifth line 352, and the ground layer 353 that is a solid pattern, similarly to the fifth-layer pattern 350 in the first embodiment.

In the fourth line 351, one end is connected to the via VIA connected to the bias pad 313f arranged in the central portion of the first-layer pattern 310, and the other end is connected to the via VIA connected to the bias pad 363f arranged at the side portion of the sixth-layer pattern.

In the fifth line 352, one end is connected to the via VIA connected to the bias pad 313h arranged in the central portion of the first-layer pattern 310, and the other end is connected to the via VIA connected to the bias pad 363h arranged at the side portion of the sixth-layer pattern.

The sixth-layer pattern 360 is a pattern on the back surface of the third substrate 300, and is a pad layer connected to the first front side pad of the first substrate 100 by the solder balls 50.

The sixth-layer pattern 360 includes pads corresponding to the first front side pads formed on the front surface of the first substrate 100 and the ground layer 366 that is a solid pattern, similarly to the sixth-layer pattern 360 in the first embodiment.

As illustrated in FIG. 18, the first resin layer 400 is a resin sealing material that is in contact with the periphery of the front surface of the first substrate 100 and the periphery of the back surface of the third substrate 300 in such a manner as to have a rectangular hollow portion 400C that is a hermetically sealed space, and is the same as the first resin layer 400 in the first embodiment.

That is, the first resin layer 400 is bonded to the resin bonding surface 400A around the front surface of the first substrate 100, and bonded to the resin bonding surface 400B around the back surface of the third substrate 300.

The first resin layer 400 does not overlap with the first wiring pattern layer constituting a transmission lines and the like formed on the front surfaces of the first semiconductor element 10 and the first dielectric substrate 101.

As illustrated in FIG. 18, the second resin layer 500 is a resin sealing material that is in contact with the periphery of the front surface of the second substrate 200 and the periphery of the front surface of the third substrate 300 in such a manner as to have a rectangular hollow portion 500C that is a hermetically sealed space, and is the same as the second resin layer 500 in the first embodiment.

That is, the second resin layer 500 is bonded to the resin bonding surface 500A around the front surface of the second substrate 200, and bonded to the resin bonding surface 500B around the front surface of the third substrate 300.

The second resin layer 500 does not overlap with the second wiring pattern layer constituting lines formed on the front surfaces of the second semiconductor element 20, the third semiconductor element 30, and the second dielectric substrate 201.

Since the semiconductor device according to the second embodiment is configured as described above, each of the input terminals 11 and 12, the output terminals 13 and 14, and the bias terminals 15 and 16 of the first semiconductor element 10 is connected to the first wiring pattern layer formed on the front surface of the first substrate 100 by a wire W, and is connected to the mounting substrate via the pad—the solder ball 50 formed on the front surface of the first substrate 100, via the pad of the sixth-layer pattern 360—the via VIA—the pad of the first-layer pattern 310—the solder ball 70 on the third substrate 300, and via the front side pad—the via VIA—the back side pad on the second substrate 200.

Each of the bias terminals 24a to 24c of the second semiconductor element 20 and the input terminal 31 and the bias terminals 34a to 34 of the third semiconductor element 30 is connected to the second wiring pattern layer formed on the front surface of the second substrate 200 by the wire W, and is connected to the mounting substrate via the front side pad—the via VIA—the back side pad formed on the side portion of the front surface of the second substrate 200.

Each of the output terminal 23 of the second semiconductor element 20 and the bias terminals 34g and 34i of the third semiconductor element 30 is connected to the second wiring pattern layer formed on the front surface of the second substrate 200 by the wire W, and is connected to the mounting substrate via the front side pad formed in the central portion on the front surface of the second substrate 200—the solder ball 70, via the pad formed in the central portion of the first-layer pattern—the via VIA—the first line 321, the second line 322, and the third line 323 on the third substrate 300—the via VIA—the pad formed at the side portion of the first-layer pattern—the solder ball 70, and via the back side pad formed at the side portion on the front surface of the second substrate 200.

Each of the bias terminals 34f and 34h of the third semiconductor element 30 is connected to the second wiring pattern layer formed on the front surface of the second substrate 200 by the wire W, and is connected to the mounting substrate via the front side pad formed in the central portion on the front surface of the second substrate 200—the solder ball 70, via the pad formed in the central portion of the first-layer pattern—the via VIA—the fourth line 351 and the fifth line 352 on the third substrate 300—the via VIA—the pad formed at the side portion the first-layer pattern—the pad-solder ball 70, and via the back side pad formed at the side portion on the front surface of the second substrate 200.

In the assembly of the semiconductor device according to the second embodiment, that is, the method for manufacturing the semiconductor device, first, the first substrate 100, the second substrate 200, and the third substrate 300 are prepared similarly to the manufacturing method in the first embodiment.

Next, similarly to the manufacturing method in the first embodiment, in a state where the third substrate 300 and the first substrate 100 are stacked on the front surface of the second substrate 200, the solder balls 50 and the solder balls 70 are melted to manufacture a stack in which the third substrate 300 is stacked on the second substrate 200 and the first substrate 100 is stacked on the third substrate 300.

Thereafter, similarly to the manufacturing method according to the first embodiment, as illustrated in FIG. 18, a resin sealing material is partially injected from the side face of the stack along the entire periphery between the second substrate 200 and the third substrate 300 to form the second resin layer 500, and the resin sealing material is partially injected from the side face of the stack along the entire periphery between the first substrate 100 and the third substrate 300 to form the first resin layer 400.

In this manner, since the second resin layer 500 is formed only around the four sides of the second dielectric substrate 201 in the second substrate 200, most of the space between the second substrate 200 and the third substrate 300 is in a hollow state.

Similarly, since the first resin layer 400 is formed only around the four sides of the first dielectric substrate 101 in the first substrate 100, most of the space between the first substrate 100 and the third substrate 300 is in a hollow state.

That is, a hermetically sealed rectangular hollow portion 500C surrounded by the second resin layer 500 is formed between the second substrate 200 and the third substrate 300, and a hermetically sealed rectangular hollow portion 400C surrounded by the first resin layer 400 is formed between the first substrate 100 and the third substrate 300.

As described above, assembly as a semiconductor device in which the third substrate 300 is stacked on the second substrate 200 and the first substrate 100 is stacked on the third substrate 300, that is, manufacturing of the semiconductor device is completed.

Therefore, similarly to the semiconductor device according to the first embodiment, since the first semiconductor element 10, the second semiconductor element 20, and the third semiconductor element 30 can be shielded from the outside air, the influence of the outside air can be reduced, impact resistance as a semiconductor device is excellent, and performance deterioration as a semiconductor device due to the first resin layer 400 and the second resin layer 500 is suppressed.

As described above, the semiconductor device according to the second embodiment has effects similar to those of the semiconductor device according to the first embodiment, and in addition, since the heat dissipation area of the front surface of the first ground conductor 130 in the first substrate 100 is large, the heat dissipation is good, and the heat dissipation as a semiconductor device is improved.

Further, since the first ground conductor 130 in the first substrate 100 is a solid ground and the wiring area can be expanded with respect to the first substrate 100, the semiconductor device can be further downsized.

### Third Embodiment

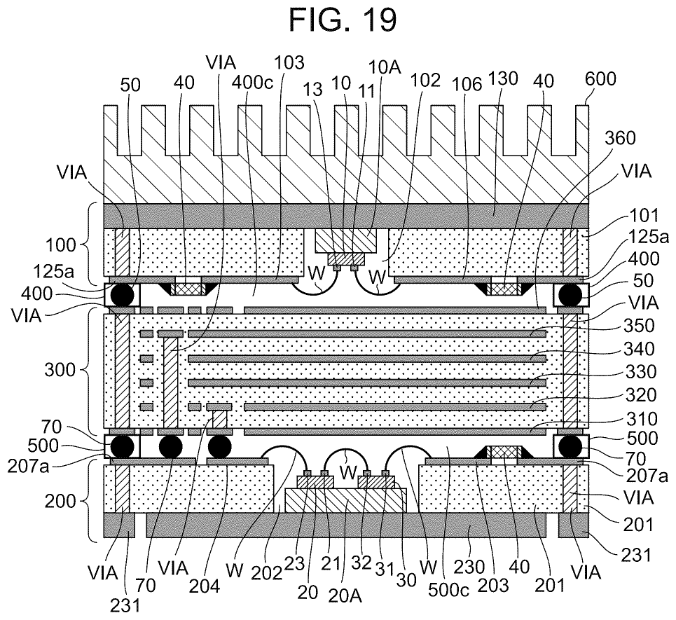

A semiconductor device according to a third embodiment will be described with reference to FIG. 19.

The semiconductor device according to the third embodiment is different from the semiconductor device according to the second embodiment in that a heat radiator 600 mounted on the back surface of the first ground conductor 130 of the first substrate 100 is provided, and the other points are the same.

As illustrated in FIG. 19, the semiconductor device according to the third embodiment includes the heat radiator 600 which is a heat radiating fin fixed to the entire back surface of the first ground conductor 130 by solder or the like.

Note that the size of the heat radiator 600 in the plane may be larger than the size of the plane of the back surface of the first ground conductor 130.

Note that, in FIG. 19, the same reference numerals as those attached in FIGS. 1 and 18 denote the same or corresponding parts.

The semiconductor device according to the third embodiment has effects similar to those of the semiconductor device according to the second embodiment, and can more efficiently dissipate heat generated by the first semiconductor element 10, thereby improving heat dissipation as a semiconductor device.

Note that, by applying the concept of the third embodiment that the heat radiator 600 is provided on the entire back surface of the first ground conductor 130 to the semiconductor device according to the first embodiment, a configuration may be employed in which, in the semiconductor device according to the first embodiment, when the second semiconductor element 20 and the third semiconductor element 30 mounted on the second substrate 200 generate a large amount of heat, the heat radiator 600, which is a heat radiating fin fixed to the entire back surface of the second substrate 200 by solder or the like, is bonded.

### Fourth Embodiment

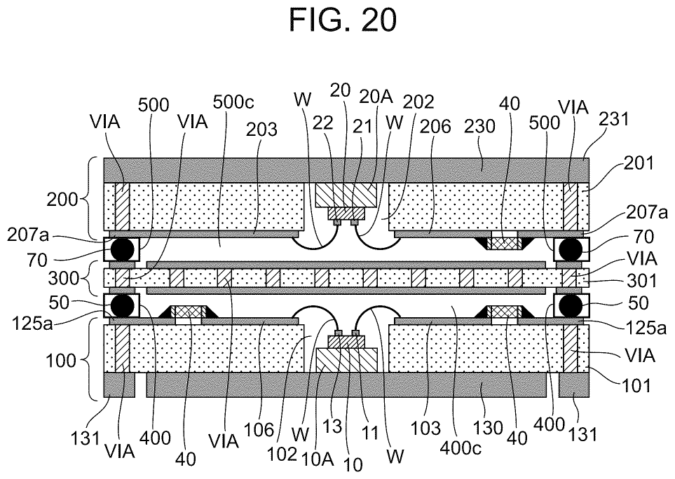

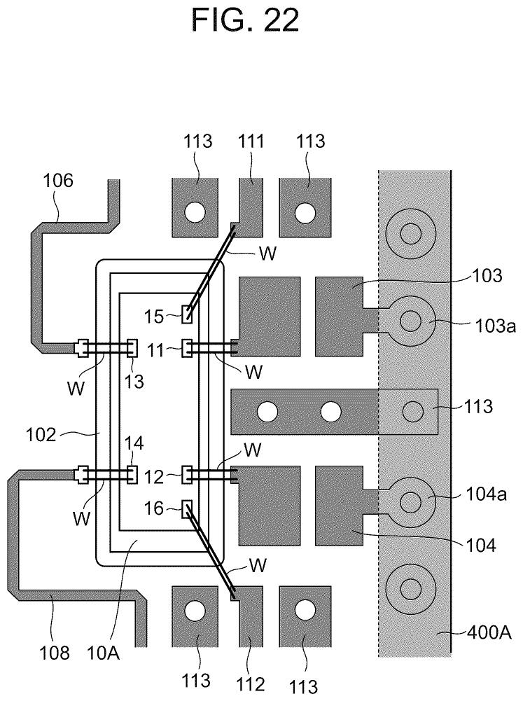

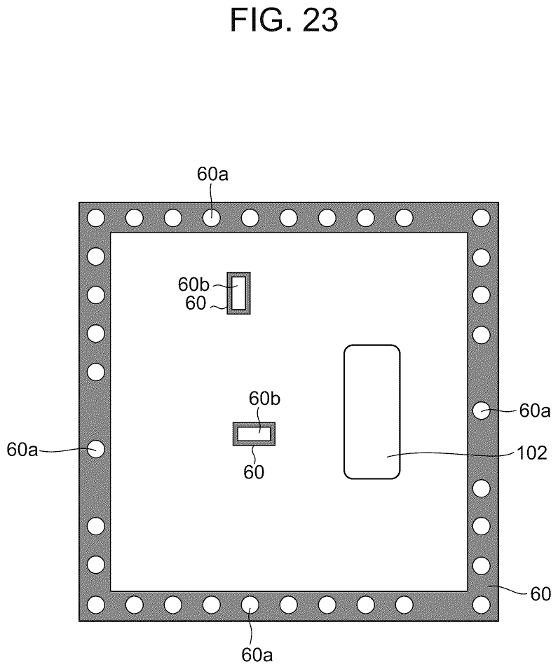

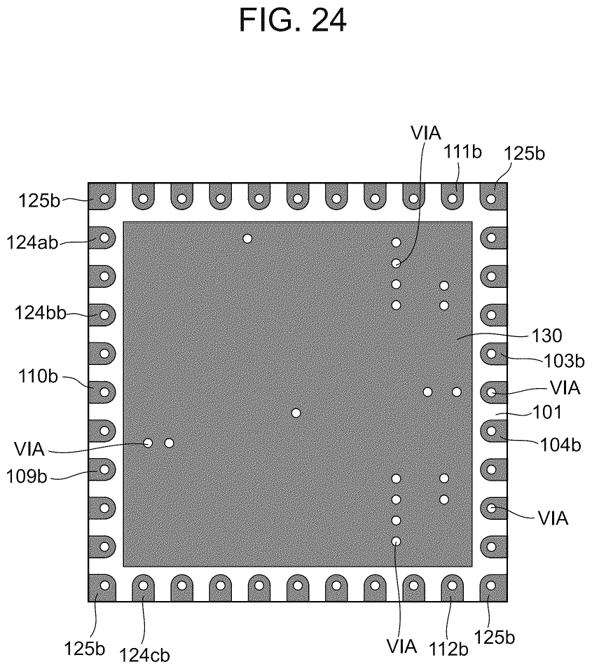

A semiconductor device according to a fourth embodiment will be described with reference to FIGS. 20 to 32.

The semiconductor device according to the fourth embodiment is different in that, while the second semiconductor element 20 and the third semiconductor element 30 are mounted on the second substrate 200 in the semiconductor device according to the first embodiment, only the second semiconductor element 20 that is a semiconductor element having a power supply control function is mounted, and accordingly, the third substrate 300 is an interposer substrate that is a single-layer substrate, and the other points are the same.

Note that, in FIGS. 20 to 32, the same reference numerals as those attached in FIGS. 1 to 17 denote the same or corresponding parts.

The semiconductor device according to the fourth embodiment is a stacked semiconductor device in which the semiconductor element 10 having a high output amplification function and the semiconductor element 20 having a power supply control function are mounted, the semiconductor element being used in a high frequency device for communication or the like.

In particular, the semiconductor device according to the fourth embodiment is a semiconductor device having high reliability and high manufacturability while achieving ultra-wideband characteristics that can substantially cover the entire region of the Sub-6 band.

As illustrated in FIG. 20, the semiconductor device according to the fourth embodiment includes a first semiconductor element 10, a second semiconductor element 20, a first substrate 100, a second substrate 200, and a third substrate 300.

The first semiconductor element 10 and the second semiconductor element 20 are the same as the first semiconductor element 10 and the second semiconductor element 20 in the first embodiment.

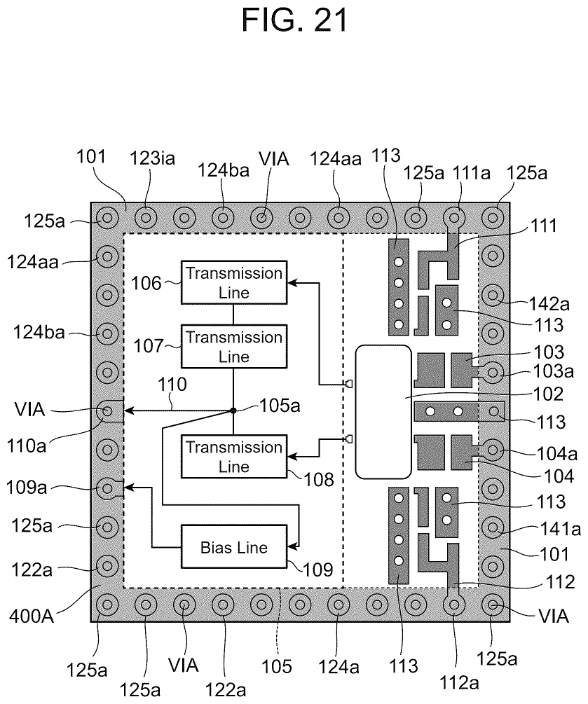

As illustrated in FIGS. 21 to 24, the basic configuration of the first substrate 100 is the same as that of the first substrate 100 according to the first embodiment.

That is, since the third semiconductor element 30 is not mounted on the second substrate 200, in the first substrate 100, the input pad 121a and the bias pads 123aa to 123ia, which are first front side pads, and the input pad 121b and the bias pads 123ab to 123ib, which are first back side pads, of the first substrate 100 with respect to the third semiconductor element in the first embodiment are set as the ground pads 125a and 125b, and one input pads 141a and 141b and the other input pads 142a and 142b, which are first front side pads and second back side pads, with respect to one input terminal 21 and the other input terminal 22 of the second semiconductor element 20 are included.

The configuration of the first substrate 100 other than those described above is the same as the configuration of the first substrate 100 in the first embodiment.

Since the pad for the third semiconductor element is not provided, the first wiring pattern in the first wiring pattern layer formed on the front surface of the first dielectric substrate 101 is slightly different in pattern from the first wiring pattern in the first wiring pattern layer formed on the front surface of the first substrate 100 in the first embodiment, but the functions are exactly the same.

As illustrated in FIG. 20, the second substrate 200 includes a second dielectric substrate 201 constituted by a single-layer insulating base material, a second wiring pattern layer and a plurality of second front side pads formed on the front surface of the second dielectric substrate 201, and a second ground conductor 230 constituted by thick copper and formed on the back surface of the second dielectric substrate 201, and a second opening 202 reaching the front surface of the second ground conductor 230 from the front surface is formed in the second dielectric substrate 201.

The second dielectric substrate 201 is the same insulating base material as the first dielectric substrate 101.

The thickness of the second dielectric substrate 201 is the same as the thickness of the first dielectric substrate 101, and is a thickness up to a manufacturing limit for forming the second opening 202.

The second wiring pattern layer is constituted by the same material and has the same thickness as the first wiring pattern layer.

In the second substrate 200, the second semiconductor element 20 is mounted in the second opening 202 via the second heat sink 20A.

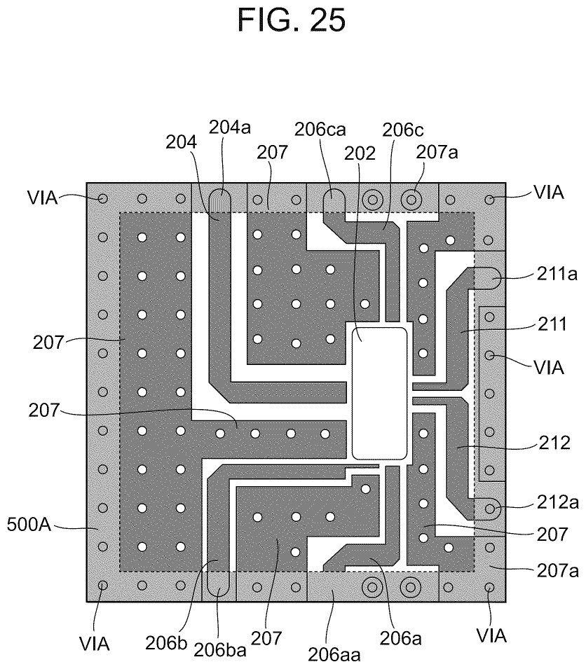

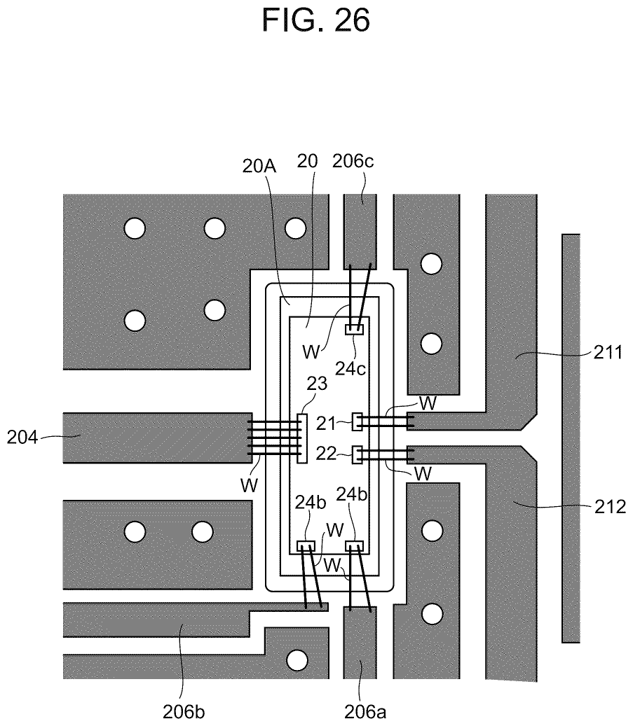

As illustrated in FIGS. 25 and 26, the second wiring pattern layer formed on the front surface of the second dielectric substrate 201 in the second substrate 200 includes two input lines 211 and 212, an output line 204, three bias lines 206a to 206c, and a plurality of ground conductors 207.

One input line 211 is connected to one input terminal 21 of the second semiconductor element 20 by wire bonding with a wire W such as a gold wire.

The other input line 212 is connected to the other input terminal 22 of the second semiconductor element 20 by wire bonding with a wire W such as a gold wire.

The number of wires W is illustrated in units of two in FIG. 26, but may be one or three or more.

The input lines 211 and 212 are collectively referred to as lines from positions where the input terminals 21 and 22 of the second semiconductor element 20 are connected to input pads 211a and 212a, respectively.

Note that, in the present fourth embodiment, the description is given using a wire, but connection using another connection member such as a gold ribbon may be used as long as the connection member has a mountable pad size.

The output line 204 is connected to the output terminal 23 of the second semiconductor element 20 by wire bonding using a wire W such as a gold wire.

The output line 204 is a generic term for a line extending from a position where the output terminal 23 of the second semiconductor element 20 is connected to the output pad 204a.

The bias lines 206a to 206c are connected to the corresponding bias terminals 24a to 24c of the second semiconductor element 20 by wire bonding with wires W.

Each of the bias lines 206a to 206c is a generic term for a line extending from a position where the bias terminals 24a to 24c of the second semiconductor element 20 are connected to the corresponding bias pads 206aa to 206ca.

Each of the input lines 211 and 212, the output line 204, and the bias lines 206a to 206c is patterned to such an extent that they are not coupled to each other, and has a pattern satisfying a required size, for example, a bent line pattern.

As illustrated in FIGS. 25 and 26, each of the plurality of ground conductors 207 is arranged between adjacent transmission lines to prevent interference between signals or the like between the adjacent transmission lines.

Each of the plurality of ground conductors 207 is electrically connected to the second ground conductor 230 formed on the back surface of the second dielectric substrate 201 by a via VIA indicated by circle marks “∘” in FIG. 25 in the ground conductor 207.

Since each of the plurality of ground conductors 207 can form an electric wall, unnecessary interference between transmission lines can be suppressed.

Note that, among the plurality of ground conductors 207, in the ground conductor 207 extending to the side of the second dielectric substrate 201 and having a line width larger than the diameter of the pad, the position of the ground conductor 207 connected to the via VIA located on the side of the second dielectric substrate 201 also serves as the ground pad 207a.

In the present fourth embodiment, the plurality of second front side pads formed on the front surface of the second dielectric substrate 201 includes 11 pads on each side formed by patterning a conductor that is a copper foil simultaneously with the wiring pattern layer along the four sides of the second dielectric substrate 201. However, the number of pads on each side is not limited to 11.

The plurality of second front side pads arranged on the four sides of the second dielectric substrate 201 includes input pads 211a and 212a, an output pad 204a, bias pads 206aa to 206ac, and ground pads 207a other than those mentioned above.

Each second front side pad is selected from the plurality of second front side pads depending on the line of the second wiring pattern.

Each of the ground pads 207a is electrically connected to the second ground conductor 230 formed on the back surface of the second dielectric substrate 201 via the via VIA penetrating the second dielectric substrate 201.

Each of the plurality of second front side pads is electrically and physically connected to each of the corresponding plurality of third front side pads of the third substrate 300 by a second connection member 70 such as a solder ball as partially illustrated in FIG. 20. Hereinafter, the second connection member 70 will be described as a solder ball 70.

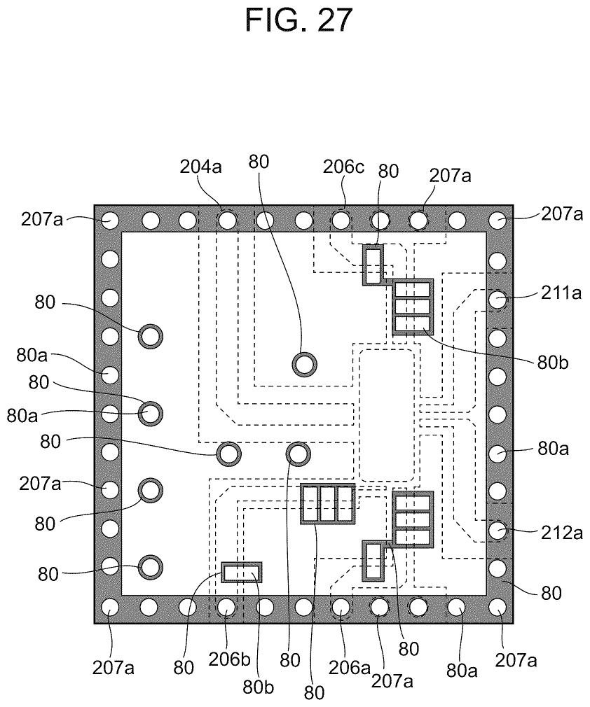

The resist film 80 is formed on the front surface of the second dielectric substrate 201, and the resist film 80 has a circular opening 80a for exposing the front surfaces of all of the plurality of second front side pads formed on the front surface of the second dielectric substrate 201 and for mounting the solder balls 70, and a rectangular opening 80b for mounting a chip component (not illustrated), as illustrated in FIG. 27.

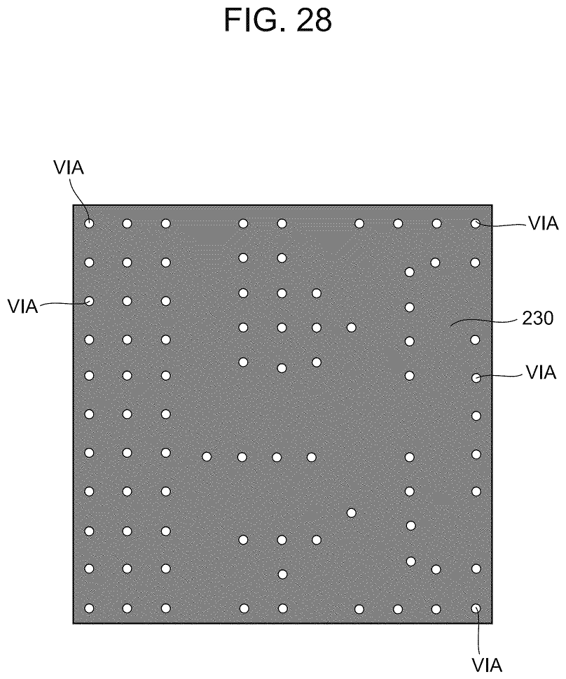

As illustrated in FIG. 28, the second ground conductor 230 formed on the back surface of the second dielectric substrate 201 is electrically connected to each of the plurality of ground conductors 207 and the ground pads 207a formed on the front surface of the second dielectric substrate 201 by a via VIA indicated by circle marks “∘” in the drawing in the second ground conductor 230.

The first substrate 100 and the second substrate 200 have the same thickness as a whole, and the thicknesses and materials of constituent elements thereof are the same, that is, the first dielectric substrate 101 and the second dielectric substrate 201 are constituted by the same material and have the same thickness, the first wiring pattern layer and the second wiring pattern layer are constituted by the same material and have the same thickness, and the first ground conductor 130 and the second ground conductor 230 are constituted by the same material and have the same thickness.

The front surface of the first substrate 100, that is, the first wiring pattern layer, and the front surface of the second substrate 200, that is, the second wiring pattern layer are arranged to face each other.

As illustrated in FIG. 20, the third substrate 300 is an interposer substrate having a single-layer structure that is arranged between the first substrate 100 and the second substrate 200 in such a manner as to face the first substrate 100 and the second substrate 200, has a plurality of third back side pads on the back surface, each of which is connected to each of the plurality of first front side pads of the first substrate 100 by a solder ball 50, has a plurality of third front side pads on the front surface, each of which is connected to each of the plurality of second front side pads of the second substrate 200 by a solder ball 70, and relays electrical connection between the first substrate 100 and the second substrate 200.

That is, the third substrate 300 includes a single-layer insulating substrate 301, a plurality of third front side pads 317, 318, 312, and 313a to 313c and a ground layer 315 formed on the front surface of the insulating substrate 301, and a plurality of third back side pads 367, 368, 362, and 363a to 363c and a ground layer 365 formed on the back surface of the insulating substrate 301.

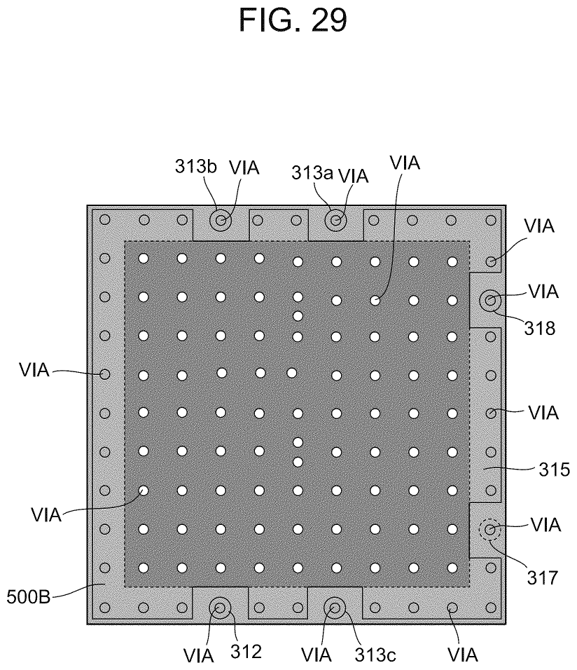

As illustrated in FIG. 29, the plurality of third front side pads 317, 318, 312, and 313a to 313c is arranged at the side portion of the insulating substrate 301 at positions facing the input pads 211a and 212a, the output pad 204a, and the bias pads 206aa to 206ca of the second substrate 200, and are connected by the solder balls 70.

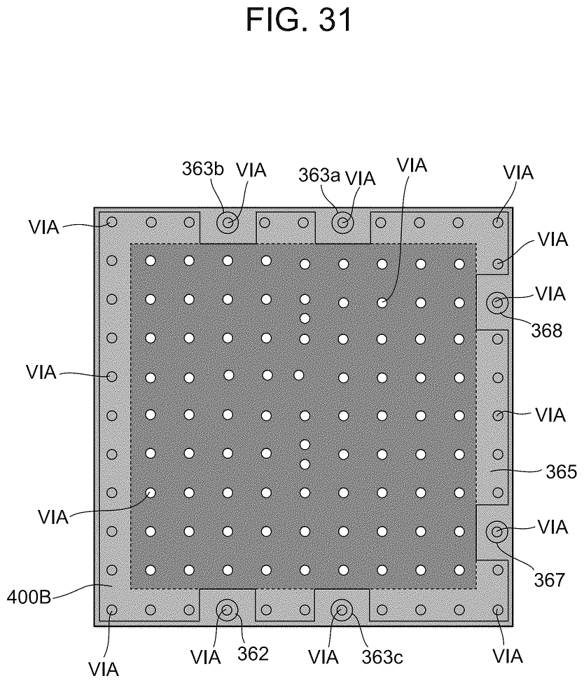

As illustrated in FIG. 31, the plurality of third back side pads 367, 368, 362, and 363a to 363c is arranged at the side portion of the insulating substrate 301 at positions facing the plurality of third front side pads 317, 318, 312, and 313a to 313c, respectively.

The plurality of third front side pads 317, 318, 312, and 313a to 313c and the plurality of third back side pads 367, 368, 362, and 363a to 363c facing each other are connected via vias VIA.

Each of the plurality of third back side pads 367, 368, 362, and 363a to 363c is connected to one input pad 141a, the other input pad 142a, the output pad 122a, and the bias pads 124aa to 124ca on the opposing first substrate 100 by the solder balls 50.

As illustrated in FIG. 29, the ground layer 315 formed on the front surface of the insulating substrate 301 is a solid pattern electrically insulated from the third front side pads 317, 318, 312, and 313a to 313c in a region excluding these pads.

The ground layer 315 is electrically connected to the ground layer 325 formed on the front surface of the insulating substrate 301 by a via VIA indicated by circle marks “∘” in FIG. 29 in the ground layer 315.

Note that, in the ground layer 315, a portion connected to the vias VIA located along the four sides of the insulating substrate 301 also serves as the ground pad 315a.

As illustrated in FIG. 31, the ground layer 365 formed on the back surface of the insulating substrate 301 is a solid pattern electrically insulated from the third back side pads 367, 368, 362, and 363a to 363c in a region excluding these pads.

Note that, in the ground layer 365, a portion connected to the vias VIA located along the four sides of the insulating substrate 301 also serves as the ground pad 365a.

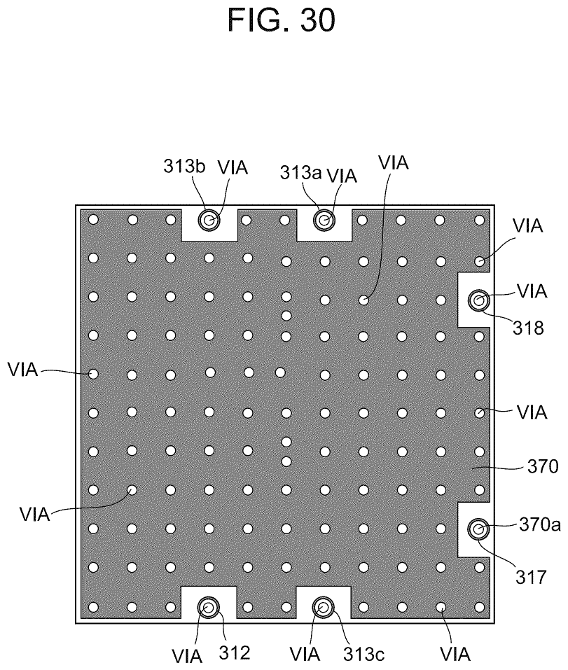

The resist film 370 is formed on the front surface of the insulating substrate 301, and as illustrated in FIG. 30, has a circular opening 370a for exposing the front surfaces of the input pads 317 and 318, the output pad 312, the bias pads 313a to 313c, and the ground pad 315a and mounting the solder balls 70.

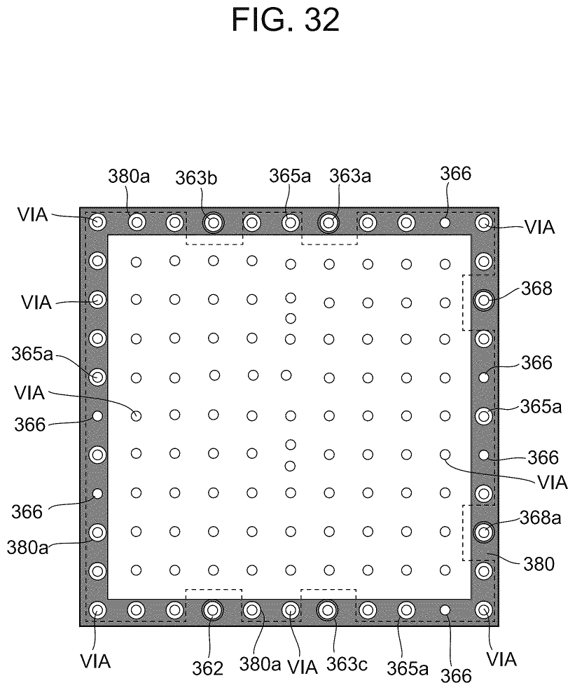

The resist film 380 is formed on the back surface of the insulating substrate 301, and as illustrated in FIG. 32, has a circular opening 380a for exposing the front surfaces of the input pads 367 and 368, the output pad 362, the bias pads 363a to 364c, and the ground pad 365a, and mounting the solder ball 50.

Note that, in FIG. 32, the resist film 380 covers the front surface at positions indicated by circle marks “∘” denoted by reference numeral 366, that is, positions facing the one input pad 103a, the other input pad 104a, the bias pad 109a, the output pad 110a, the bias pad 111a, and the bias pad 112a in the first substrate 100.

As described above, in the third substrate 300, since the regions other than the pads excluding the ground pads on both the front surface and the back surface of the insulating substrate 301 are the ground layers 315 and 365, unnecessary coupling between the first semiconductor element 10 mounted on the first substrate 100 and the second semiconductor element 20 mounted on the second substrate 200 can be suppressed.

As a result, the independent first substrate 100, third substrate 300, and second substrate 200 can be stacked in the vertical direction, and the semiconductor device itself can be downsized.

As illustrated in FIG. 20, the first resin layer 400 is a resin sealing material that is in contact with the periphery of the front surface of the first substrate 100 and the periphery of the back surface of the third substrate 300 in such a manner as to have a rectangular hollow portion 400C that is a hermetically sealed space, and is the same as the first resin layer 400 in the first embodiment.

The first resin layer 400 is bonded to the resin bonding surface 400A around the front surface of the first substrate 100 as illustrated in FIG. 21, and is bonded to the resin bonding surface 400B around the back surface of the third substrate 300 as illustrated in FIG. 31.

The first resin layer 400 does not overlap with the first wiring pattern layer constituting a transmission lines and the like formed on the front surfaces of the first semiconductor element 10 and the first dielectric substrate 101.

As illustrated in FIG. 20, the second resin layer 500 is a resin sealing material that is in contact with the periphery of the front surface of the second substrate 200 and the periphery of the front surface of the third substrate 300 in such a manner as to have a rectangular hollow portion 500C that is a hermetically sealed space, and is the same as the second resin layer 500 in the first embodiment.

The second resin layer 500 is bonded to the resin bonding surface 500A around the front surface of the second substrate 200 as illustrated in FIG. 25, and is bonded to the resin bonding surface 500B around the front surface of the third substrate 300 as illustrated in FIG. 29.

The second resin layer 500 does not overlap with the second wiring pattern layer constituting lines formed on the front surfaces of the second semiconductor element 20, the third semiconductor element 30, and the second dielectric substrate 201.

In the assembly of the semiconductor device according to the fourth embodiment, that is, the method for manufacturing the semiconductor device, first, the first substrate 100, the second substrate 200, and the third substrate 300 are prepared similarly to the manufacturing method in the first embodiment.

Next, similarly to the manufacturing method in the first embodiment, in a state where the third substrate 300 and the second substrate 200 are stacked on the front surface of the first substrate 100, the solder balls 50 and the solder balls 70 are melted to manufacture a stack in which the third substrate 300 is stacked on the first substrate 100 and the second substrate 200 is stacked on the third substrate 300.

Thereafter, similarly to the manufacturing method according to the first embodiment, as illustrated in FIG. 20, a resin sealing material is partially injected from the side face of the stack along the entire periphery between the first substrate 100 and the third substrate 300 to form the first resin layer 400, and the resin sealing material is partially injected from the side face of the stack along the entire periphery between the second substrate 200 and the third substrate 300 to form the second resin layer 500.

In this manner, since the first resin layer 400 is formed only around the four sides of the first dielectric substrate 101 in the first substrate 100, most of the space between the first substrate 100 and the third substrate 300 is in a hollow state.

Similarly, since the second resin layer 500 is formed only around the four sides of the second dielectric substrate 201 in the second substrate 200, most of the space between the second substrate 200 and the third substrate 300 is in a hollow state.

That is, a hermetically sealed rectangular hollow portion 400C surrounded by the first resin layer 400 is formed between the first substrate 100 and the third substrate 300, and a hermetically sealed rectangular hollow portion 500C surrounded by the second resin layer 500 is formed between the second substrate 200 and the third substrate 300.

As described above, assembly as a semiconductor device in which the third substrate 300 is stacked on the first substrate 100 and the second substrate 200 is stacked on the third substrate 300, that is, manufacturing of the semiconductor device is completed.

Therefore, similarly to the semiconductor device according to the first embodiment, since the first semiconductor element 10 and the second semiconductor element 20 can be shielded from the outside air, the influence of the outside air can be reduced, impact resistance as a semiconductor device is excellent, and performance deterioration as a semiconductor device due to the first resin layer 400 and the second resin layer 500 is suppressed.

As described above, similarly to the semiconductor device according to the first embodiment, the semiconductor device according to the fourth embodiment has good diffusibility with respect to heat generated by the first semiconductor element 10 and the second semiconductor element 20 by the first ground conductor 130 and the second ground conductor 230, improves heat dissipation as a semiconductor device, reduces warpage of the first substrate 100, the second substrate 200, and the third substrate 300, can compensate for improvement in yield and stability in performance as a semiconductor device, and improves reliability as a semiconductor device.

In addition, in the semiconductor device according to the fourth embodiment, similarly to the semiconductor device according to the first embodiment, since the output combining circuit 105 can be formed as a wiring pattern on the front surface of the first substrate 100, the influence of unnecessary parasitic components can be reduced, and deterioration of electrical characteristics can be prevented.

Further, in the semiconductor device according to the fourth embodiment, similarly to the semiconductor device according to the first embodiment, since the third substrate 300 has the ground layer 315 and the ground layer 365 which are solid patterns on the front surface and the back surface of the insulating substrate 301, respectively, unnecessary coupling between the first semiconductor element 10 and the second semiconductor element 20 can be suppressed, the first substrate 100, the third substrate 300, and the second substrate 200 can be stacked in the vertical direction, and the semiconductor device itself can be miniaturized.

In the semiconductor device according to the fourth embodiment, since the first substrate 100 and the second substrate 200 can be formed into a stacked package as a stacked structure in such a manner as to sandwich the third substrate 300, reliability as a circuit is improved.

In addition, in the semiconductor device according to the fourth embodiment, similarly to the semiconductor device according to the first embodiment, the periphery of the front surface of the first substrate 100 and the periphery of the back surface of the third substrate 300 are bonded by the first resin layer 400 having the hollow portion 400C, and the periphery of the front surface of the second substrate 200 and the periphery of the front surface of the third substrate 300 are bonded by the second resin layer 500 having the hollow portion 500C, so that various transmission lines formed on the first substrate 100 and the second substrate 200 and the first semiconductor element 10 and the second semiconductor element 20 are not overlapped with the resin sealing material forming the first resin layer 400 and the second resin layer 500.

Therefore, deterioration of electrical characteristics due to the influence of the physical properties of the resin sealing material by the first resin layer 400 and the second resin layer 500 can be reduced.

In addition, since the bonding area between the first substrate 100 and the third substrate 300 and the bonding area between the second substrate 200 and the third substrate 300 are increased, it becomes strong against an impact such as vibration from the outside.

In a case where the semiconductor device constitutes an amplifier, the first resin layer 400 and the second resin layer 500 prevent inflow of high temperature and high humidity air, which is one of factors of characteristic degradation as an amplifier, and environmental resistance is improved.

Note that in the first to fourth embodiments, each of the first ground conductor 130 in the first substrate 100 and the second ground conductor 230 in the second substrate 200 is constituted by thick copper, but in a case where necessary manufacturability and reliability can be ensured, from the viewpoint of reduction in the number of manufacturing steps and cost reduction, a normal copper foil thickness is set to each of the first ground conductor 130 and the second ground conductor 230, and a resin substrate or a ceramic substrate having a normal copper foil thickness may be used for each of the first dielectric substrate 101 and the second dielectric substrate 201.

Further, while an example in which the semiconductor device according to each of the first to third embodiments is applied to a broadband GaN amplifier that is used in a high frequency device for communication or the like and switches between a Doherty mode and an out-fading mode for each frequency, and an example in which the semiconductor device according to the fourth embodiment is applied to a stacked semiconductor device that is used in a high frequency device for communication or the like and in which a semiconductor element having a high output amplification function and a semiconductor element having a power supply control function are mounted have been mainly described, the semiconductor device according to each of the first to fourth embodiments may be applied to a semiconductor device that is a high frequency module such as a solid state power amplifier (SSPA) module, an antenna device in which an antenna is connected to an output unit of the high frequency module, and an array antenna module in which the high frequency module is connected to each of a plurality of antennas by using a plurality of the high frequency modules.

Even when the semiconductor devices according to the first to fourth embodiments are applied to these modules, antenna devices, and array antenna devices, the miniaturization, high heat dissipation, reliability, environmental resistance, impact resistance, and ultra-wideband characteristics described in the first to fourth embodiments can be obtained.

Note that free combinations of the individual embodiments, modifications of any components of the individual embodiments, or omissions of any components in the individual embodiments are possible.

### INDUSTRIAL APPLICABILITY

The semiconductor device according to the present disclosure can be applied to a semiconductor device on which a semiconductor element that is a high-power amplifier is mounted in the field of high frequency devices for communication or the like, and can be applied to a GaN amplifier, a solid semiconductor amplifier, an antenna device using a solid semiconductor amplifier, and an array antenna device including a plurality of antenna devices.

### REFERENCE SIGNS LIST

10: First semiconductor element, 10A: First heat sink, 20: Second semiconductor element, 20A: Second heat sink, 30: Third semiconductor element, 40: Chip component, 50: First connection member, 70: Second connection member, 100: First substrate, 101: First dielectric substrate, 102: First opening, 103 and 104: Input line, 105: Output combining circuit, 106: First transmission line, 107: Second transmission line, 108: Third transmission line, 109: Bias line on output side, 110: Output line, 111 and 112: Bias line on input side, 113: Ground conductor, 130: First ground conductor, 200: Second substrate, 201: Second dielectric substrate, 202: Second opening, 203: Input line, 204: Output line, 205a to 205i: Bias line on input side, 206a to 206c: Bias line on output side, 207: Ground conductor, 230: Second ground conductor, 300: Third substrate, 310 to 360: First-layer pattern to sixth-layer pattern, 301: Insulating substrate, 400: First resin layer, 500: Second resin layer, 600: Heat radiator

What is claimed is:

1. A semiconductor device comprising:
a first substrate on which a first semiconductor element is mounted, the first substrate including a plurality of first front side pads arranged around a front surface on a side on which the first semiconductor element is mounted;
a second substrate on which a second semiconductor element is mounted, the second substrate including a plurality of second front side pads arranged around a front surface on a side on which the second semiconductor element is mounted, the second substrate being arranged in such a manner that the front surfaces face each other with respect to the first substrate;
a third substrate disposed between the first substrate and the second substrate in such a manner as to face the front surface of the first substrate and the front surface of the second substrate, the third substrate having a plurality of third back side pads arranged around a back surface in such a manner as to face each of a plurality of first front side pads in the first substrate, and a plurality of third front side pads arranged around a front surface in such a manner as to face each of the plurality of second front side pads in the second substrate;
a plurality of first connection members each electrically connecting a corresponding first front side pad of a plurality of first front side pads on the first substrate and a corresponding third back side pad of a plurality of third back side pads on the third substrate;
a plurality of second connection members each electrically connecting a corresponding second front side pad of the plurality of second front side pads on the second substrate and a corresponding third front side pad of the plurality of third front side pads on the third substrate;
a first resin layer that is in contact with a periphery of the front surface of the first substrate and a periphery of the back surface of the third substrate and has a hollow portion; and
a second resin layer that is in contact with a periphery of the front surface of the second substrate and a periphery of the back surface of the third substrate and has a hollow portion, wherein
the first substrate includes a first dielectric substrate in which the plurality of first front side pads is formed around a front surface, a first wiring pattern layer formed on the front surface of the first dielectric substrate, and a first ground conductor constituted by thick copper formed on a back surface of the first dielectric substrate, and the first semiconductor element electrically connected to a line constituting the first wiring pattern layer is mounted and fixed on a front surface of the first ground conductor in a first opening reaching the front surface of the first ground conductor from the front surface of the first dielectric substrate, and
the second substrate includes a second dielectric substrate in which the plurality of second front side pads is formed around a front surface, a second wiring pattern layer formed on the front surface of the second dielectric substrate, and a second ground conductor constituted by thick copper formed on a back surface of the second dielectric substrate, and the second semiconductor element electrically connected to a line constituting the second wiring pattern layer is mounted and fixed on a front surface of the second ground conductor in a second opening reaching the front surface of the second ground conductor from the front surface of the second dielectric substrate.

2. The semiconductor device according to claim 1, wherein
the first dielectric substrate in the first substrate and the second dielectric substrate in the second substrate are constituted by a same material and have a same thickness,
the first wiring pattern layer formed on the front surface of the first dielectric substrate and the second wiring pattern layer formed on the front surface of the second dielectric substrate are constituted by a same material and have a same thickness, and
the first ground conductor in the first substrate and the second ground conductor in the second substrate are constituted by a same material and have a same thickness.

3. A semiconductor device comprising:
a first substrate on which a first semiconductor element is mounted, the first substrate including a plurality of first front side pads arranged around a front surface on a side on which the first semiconductor element is mounted;
a second substrate on which a second semiconductor element is mounted, the second substrate including a plurality of second front side pads arranged around a front surface on a side on which the second semiconductor element is mounted, the second substrate being arranged in such a manner that the front surfaces face each other with respect to the first substrate;
a third substrate disposed between the first substrate and the second substrate in such a manner as to face the front surface of the first substrate and the front surface of the second substrate, the third substrate having a plurality of third back side pads arranged around a back surface in such a manner as to face each of a plurality of first front side pads in the first substrate, and a plurality of third front side pads arranged around a front surface in such a manner as to face each of the plurality of second front side pads in the second substrate;
a plurality of first connection members each electrically connecting a corresponding first front side pad of a plurality of first front side pads on the first substrate and a corresponding third back side pad of a plurality of third back side pads on the third substrate;
a plurality of second connection members each electrically connecting a corresponding second front side pad of the plurality of second front side pads on the second substrate and a corresponding third front side pad of the plurality of third front side pads on the third substrate;
a first resin layer that is in contact with a periphery of the front surface of the first substrate and a periphery of the back surface of the third substrate and has a hollow portion; and
a second resin layer that is in contact with a periphery of the front surface of the second substrate and a periphery of the back surface of the third substrate and has a hollow portion,
wherein the third substrate has a ground layer that is a solid pattern on each of the front surface and the back surface.

4. The semiconductor device according to claim 1, wherein
the first semiconductor element is a semiconductor element having a high output amplification function,
the second semiconductor element is a semiconductor element having a power supply control function, and
the third substrate is a dielectric substrate that relays electrical connection between the first substrate and the second substrate.

5. The semiconductor device according to claim 1, wherein
the first semiconductor element is a semiconductor element having a high output amplification function,
the second semiconductor element is a semiconductor element having a power supply control function, and
the third substrate is a dielectric substrate that relays electrical connection between the first substrate and the second substrate,
the semiconductor device further comprising a third semiconductor element having a driver amplification function, the third semiconductor element being electrically connected to the line constituting the second wiring pattern layer on the front surface of the second ground conductor in the second opening of the second substrate.

6. The semiconductor device according to claim 1, wherein
the first semiconductor element is a semiconductor element having a high output amplification function,
the second semiconductor element is a semiconductor element having a power supply control function,
the plurality of first front side pads on the first substrate is arranged around the first dielectric substrate in such a manner as to surround the first wiring pattern, and at least one of the plurality of second front side pads on the second substrate is arranged in a central portion of the front surface of the second dielectric substrate, and a rest of the second front side pads is arranged around the second dielectric substrate in such a manner as to surround the second wiring pattern.

7. The semiconductor device according to claim 1, wherein
the first semiconductor element is a semiconductor element having a high output amplification function,
the second semiconductor element is a semiconductor element having a power supply control function,
at least one of the plurality of second front side pads formed on the front surface of the second dielectric substrate is arranged in a central portion of the front surface of the second dielectric substrate, and
the third substrate is a substrate that relays electrical connection between a second front side pad arranged in a central portion of the second substrate and a second front side pad arranged at a side portion of the second substrate.

8. The semiconductor device according to claim 1, further comprising a heat radiator mounted on a back surface of the first ground conductor in the first substrate.

9. The semiconductor device according to claim 1, wherein
the third substrate has an intermediate layer pattern between an uppermost layer pattern located on the front surface having the third front side pads and a lowermost layer pattern located on a back surface having the third back side pads, and
the intermediate layer pattern includes a line for electrically connecting the third front side pad and the third back side pad corresponding to the third front side pad.

10. The semiconductor device according to claim 9, wherein
the intermediate layer pattern includes a first intermediate layer pattern and a second intermediate layer pattern that are arranged to face each other, and
a third intermediate layer pattern that is arranged between the first intermediate layer pattern and the second intermediate layer pattern in such a manner as to face the first intermediate layer pattern and the second intermediate layer pattern and has a region other than a via excluding a via set to a ground potential as a ground layer.

11. The semiconductor device according to claim 1, wherein
the first semiconductor element is a semiconductor element having a high output amplification function,
the second semiconductor element is a semiconductor element having a power supply control function, and
the third back side pad of the third substrate is formed on a back surface of a single-layer insulating substrate, and the third front side pad of the third substrate is formed on a front surface of the single-layer insulating substrate.

12. The semiconductor device according to claim 1, wherein
the first semiconductor element is a semiconductor element having a high output amplification function, two output terminals, and a characteristic impedance of a 100Ω system, and
an output combining circuit including a first transmission line and a second transmission line connected in series between an output branch point and a first output terminal of the first semiconductor element, and a third transmission line connected between the output branch point and a second output terminal of the first semiconductor element is formed in the first wiring pattern layer in the first substrate, and
characteristic impedances of the first transmission line, the second transmission line, and the third transmission line are 100Ω, and electrical lengths of the first transmission line, the second transmission line, and the third transmission line are 50 degrees to 90 degrees.

13. The semiconductor device according to claim 12, wherein the first transmission line, the second transmission line, and the third transmission line are in a hollow portion of the first resin layer.

14. The semiconductor device according to claim 12, wherein the second semiconductor element is a semiconductor element having a power supply control function.

15. The semiconductor device according to claim 14, further comprising a third semiconductor element having a driver amplification function, the third semiconductor element being mounted and fixed on the front surface of the second ground conductor of the second substrate via a second heat sink in the second opening of the second substrate, and electrically connected to the line constituting the second wiring pattern layer of the second substrate.

16. A method for manufacturing a semiconductor device, the method comprising:
preparing a first substrate on which a first semiconductor element is mounted, the first substrate including a plurality of first front side pads arranged around a front surface on a side on which the first semiconductor element is mounted, a second substrate on which a second semiconductor element is mounted, the second substrate including a plurality of second front side pads arranged around a front surface on a side on which the second semiconductor element is mounted, and a third substrate including a plurality of third back side pads around a back surface and a plurality of third front side pads around a front surface; making the front surface of the third substrate face the front surface of the first substrate in a state where respective corresponding pads of the plurality of first front side pads of the first substrate and the plurality of third back side pads of the third substrate face each other, and arranging a plurality of first connection members electrically connecting the pads to each other between the corresponding pads;
making the front surface of the second substrate face the front surface of the third substrate in a state where respective corresponding pads of the plurality of third front side pads of the third substrate and the plurality of second front side pads of the second substrate face each other, and arranging a plurality of second connection members electrically connecting the pads to each other between the corresponding pads;
heating in a state where the third substrate and the second substrate are stacked on the front surface of the first substrate, mounting and fixing the third substrate on the first substrate by the plurality of first connection members, and mounting and fixing the second substrate on the third substrate to manufacture a stack;
partially injecting a resin sealing material from a side face of the stack along an entire periphery between the first substrate and the third substrate to form a first resin layer having a hollow portion and being in contact with a periphery of the front surface of the first substrate and a periphery of the back surface of the third substrate; and
partially injecting a resin sealing material from a side face of the stack along an entire periphery between the second substrate and the third substrate to form a second resin layer having a hollow portion and being in contact with a periphery of the front surface of the second substrate and a periphery of the back surface of the third substrate.

17. A method for manufacturing a semiconductor device, the method comprising:
preparing a first substrate on which a first semiconductor element is mounted, the first substrate including a plurality of first front side pads arranged around a front surface on a side on which the first semiconductor element is mounted, a second substrate on which a second semiconductor element is mounted, the second substrate including a plurality of second front side pads arranged around a front surface on a side on which the second semiconductor element is mounted;
making the front surface of the second substrate face the front surface of the first substrate in a state where respective corresponding pads of a plurality of first front side pads of the first substrate and a plurality of second front side pads of the second substrate face each other, and arranging a plurality of connection members each of which electrically connects the pads between the corresponding pads;
heating the second substrate in a state where the second substrate is stacked on the front surface of the first substrate, and mounting and fixing the second substrate on the first substrate by the plurality of connection members to manufacture a stacked body; and
partially injecting a resin sealing material from a side face of the stack along an entire periphery between the first substrate and the second substrate to form a resin layer having a hollow portion and being in contact with a periphery of the front surface of the first substrate and a periphery of the front surface of the second substrate.
